(19) United States
(12) Patent Application Publication
(10) Pub. No.: US 2025/0234528 A1
(43) Pub. Date: Jul. 17, 2025

(54) SEMICONDUCTOR MEMORY DEVICE AND METHOD FOR FABRICATING THE SAME

(71) Applicant: Samsung Electronics Co., Ltd., Suwon-si (KR)

(72) Inventors: Yang Doo Kim, Suwon-si (KR); Sang Wuk Park, Suwon-si (KR); Min Kyu Suh, Suwon-si (KR); Geon Yeop Lee, Suwon-si (KR); Do Keun Lee, Suwon-si (KR); Ji Hye Lee, Suwon-si (KR); Je-Woo Han, Suwon-si (KR)

(21) Appl. No.: 18/782,294

(22) Filed: Jul. 24, 2024

(30) Foreign Application Priority Data
Jan. 15, 2024 (KR) 10-2024-0006070

(51) Int. Cl. H10B 12/00

(52) U.S. Cl. CPC H10B 12/50; H10B 12/09; H10B 12/315

(57) ABSTRACT

There is provided a semiconductor memory device that includes a peri-gate structure on a substrate, a bit line, an active pattern that includes a first surface and a second surface opposite to each other, and a first side wall and a second side wall opposite to each other, and the first surface of the active pattern contacts the bit line. The semiconductor memory device includes a word line on the first side wall of the active pattern, a contact structure, and includes an upper surface and a bottom surface opposite to each other. The bottom surface of the contact structure contacts the second surface of the active pattern and a data storage pattern on the upper surface of the contact structure, and includes a lower electrode and a capacitor dielectric film. The capacitor dielectric film is in contact with the side wall of the contact structure.

### CROSS-REFERENCE TO RELATED APPLICATION

This application claims priority from Korean Patent Application No. 10-2024-0006070 filed on Jan. 15, 2024 in the Korean Intellectual Property Office, and all the benefits accruing therefrom under 35 U.S.C. 119, the contents of which in its entirety are herein incorporated by reference.

### BACKGROUND

The present invention relates to a semiconductor memory device and a method for fabricating the same, and more specifically, to a semiconductor memory device including a vertical channel transistor (VCT) and a method for fabricating the same.

There is a need to increase the degree of integration of semiconductor memory devices to satisfy excellent performance and low price desired by consumers. In the case of the semiconductor memory device, because the degree of integration is an important factor in determining the price of a product, an increased degree of integration is particularly desired.

In the case of a two-dimensional or planar semiconductor memory device, the degree of integration is mainly determined by an area occupied by unit memory cells, and is therefore greatly affected by the level of fine pattern forming technology. However, since ultra-expensive apparatuses are required to miniaturize the pattern, the degree of integration of the two-dimensional semiconductor memory device is increasing, but is still limited. Accordingly, semiconductor memory devices that include vertical channel transistors whose channels extend in a vertical direction have been proposed.

### SUMMARY

Embodiments of the present invention provide a semiconductor memory device having improved integration and electrical characteristics.

Embodiments of the present invention also provide a method for fabricating a semiconductor memory device having improved integration and electrical characteristics.

However, embodiments of the present invention are not restricted to the one set forth herein. The above and other embodiments of the present invention will become more apparent to one of ordinary skill in the art to which the present invention pertains by referencing the detailed description of the present invention given below.

According to some embodiments of the present disclosure, there is provided a semiconductor memory device comprising a peri-gate structure on a substrate, a bit line on the peri-gate structure and extends in a first direction, an active pattern on the bit line, and includes a first surface and a second surface opposite to each other in a second direction, and a first side wall and a second side wall opposite to each other in the first direction, the first surface of the active pattern is in contact with the bit line, a word line on the first side wall of the active pattern, and extends in a third direction that intersects the first direction and the second direction; a contact structure on the active pattern, and includes an upper surface and a bottom surface opposite to each other in the second direction, the bottom surface of the contact structure is in contact with the second surface of the active pattern and a data storage pattern on the upper surface of the contact structure, and includes a lower electrode and a capacitor dielectric film, the contact structure includes a side wall between the upper surface of the contact structure and the bottom surface of the contact structure, and the capacitor dielectric film extends along the side wall of the contact structure, and is in contact with the side wall of the contact structure.

According to some embodiments of the present disclosure, there is provided a semiconductor memory device comprising a peri-gate structure on a substrate, a bit line on the peri-gate structure, and extends in a first direction, an active pattern on the bit line, and includes a first surface and a second surface opposite to each other in a second direction, and a first side wall and a second side wall opposite to each other in the first direction, the first surface of the active pattern is in contact with the bit line, a word line on the first side wall of the active pattern on the bit line, and extends in a third direction that intersects the first direction and the second direction, a contact structure on the active pattern, and includes an upper surface and a bottom surface opposite to each other in the second direction, the bottom surface of the contact structure is in contact with the second surface of the active pattern and a data storage pattern on the upper surface of the contact structure The data storage pattern includes a lower electrode in contact with the upper surface of the contact structure, a capacitor dielectric film on the lower electrode, and an upper electrode on the capacitor dielectric film, the upper electrode includes a bottom surface that faces the bit line, and a distance from the upper surface of the bit line to the upper surface of the contact structure is greater than a distance from the upper surface of the bit line to the bottom surface of the upper electrode.

According to some embodiments of the present disclosure, there is provided a semiconductor memory device comprising a peri-gate structure on a substrate, a bit line on the peri-gate structure, and extends in a first direction, a shielding conductive pattern on the peri-gate structure, and includes a shielding conductive line pattern extending in the first direction along a side wall of the bit line, a word line on the bit line and the shielding conductive pattern, extends in a second direction, and includes an upper surface and a bottom surface opposite to each other in a third direction, the bottom surface of the word line faces the bit line a back gate electrode on the bit line and the shielding conductive pattern, extends in the second direction, and includes an upper surface and a bottom surface opposite to each other in the third direction, the bottom surface of the back gate electrode faces the bit line, a word line capping pattern on the upper surface of the word line, a back gate capping pattern on the upper surface of the back gate electrode, an active pattern between the word line and the back gate electrode, and includes a first surface and a second surface opposite to each other in the third direction, the first surface of the active pattern is in contact with the bit line, a contact structure on the active pattern, and connected to the second side of the active pattern and a data storage pattern on the contact structure, and includes a lower electrode and a capacitor dielectric film, and the capacitor dielectric film is in contact with the word line capping pattern and the back gate capping pattern.

According to some embodiments of the present disclosure, there is provided a method for fabricating a semiconductor memory device comprising providing a first substrate which includes a semiconductor substrate, a buried insulating layer, and an active layer, forming a back gate electrode extending in a first direction in the active layer, patterning the active layer to form first and second active patterns on the buried insulating layer on first and second sides of the back gate electrode, forming a first word line and a second word line on the buried insulating layer on the first and second sides of the back gate electrode, the first active pattern is between the first word line and the back gate electrode, and the second active pattern is between the second word line and the back gate electrode, forming bit lines extending in a second direction across the first and second word lines, on the first and second active patterns, forming a peri-gate structure on a second substrate, bonding the first substrate and the second substrate such that the bit lines and the peri-gate structure face each other, forming a metal mask pattern on the semiconductor substrate of the first substrate, forming a semiconductor mold pattern on the buried insulating layer, by removing the semiconductor substrate that overlaps the metal mask pattern in a third direction that intersects the first and second directions, forming a sacrificial mold film that wraps the semiconductor mold pattern, on the buried insulating layer, forming a lower electrode hole that exposes the first active pattern and the second active pattern in the sacrificial mold film, by removing a part of the buried insulating layer and the semiconductor mold pattern, sequentially forming a contact structure and a lower electrode in the lower electrode hole, after forming the lower electrode, removing the sacrificial mold film to expose a side wall of the lower electrode and a side wall of the contact structure and forming a capacitor dielectric film and an upper electrode on the lower electrode and the contact structure.

### BRIEF DESCRIPTION OF THE DRAWINGS

The above and other embodiments and features of the present disclosure will become more apparent by describing in detail example embodiments thereof with reference to the attached drawings, in which:

FIG. 1 is a layout diagram for explaining a semiconductor memory device according to some embodiments.

FIG. 2 is a cross-sectional view taken along lines A-A and B-B of FIG. 1.

FIG. 3 is a cross-sectional view taken along lines C-C and D-D of FIG. 1.

FIG. 4 is an enlarged view of a portion P of FIG. 4.

FIGS. 5 to 9 are enlarged views of a portion Q of FIG. 2.

FIGS. 10 to 14 are diagrams for explaining a semiconductor memory device according to some embodiments, respectively.

FIGS. 15 and 16 are diagrams for explaining a semiconductor memory device according to some embodiments.

FIGS. 17 and 18 are diagrams for explaining a semiconductor memory device according to some embodiments.

FIGS. 19 and 20 are diagrams for explaining a semiconductor memory device according to some embodiments, respectively.

FIGS. 21 to 57 are diagrams for explaining a method for fabricating a semiconductor memory device according to some embodiments.

### DETAILED DESCRIPTION OF THE EMBODIMENTS

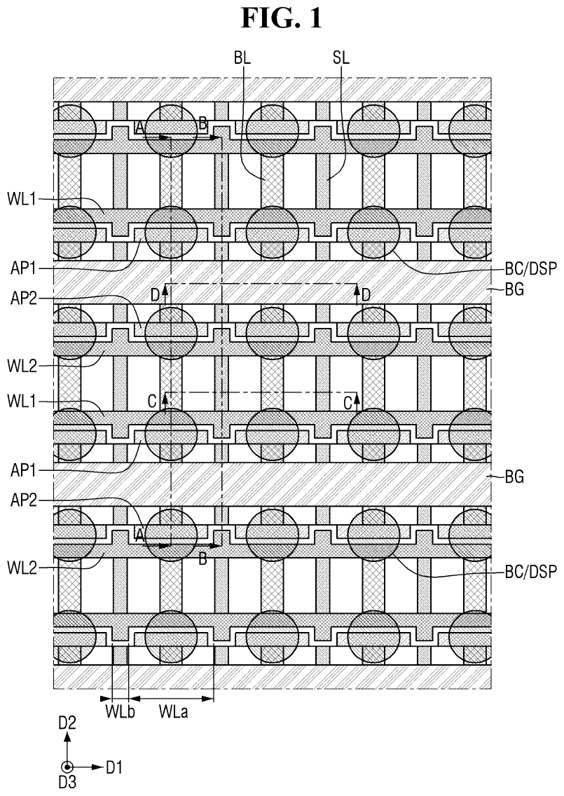

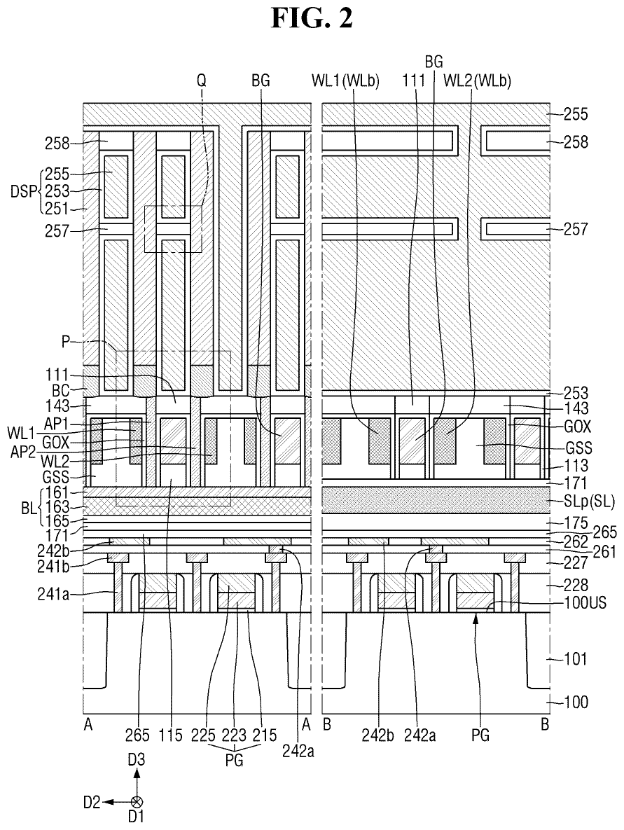

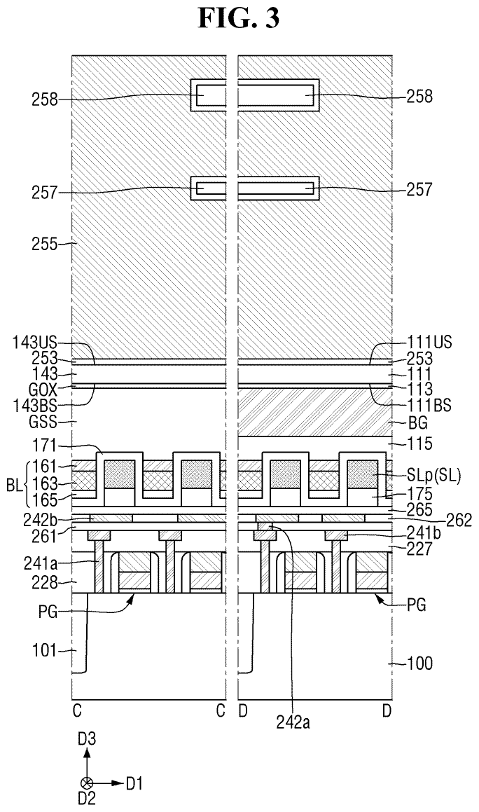

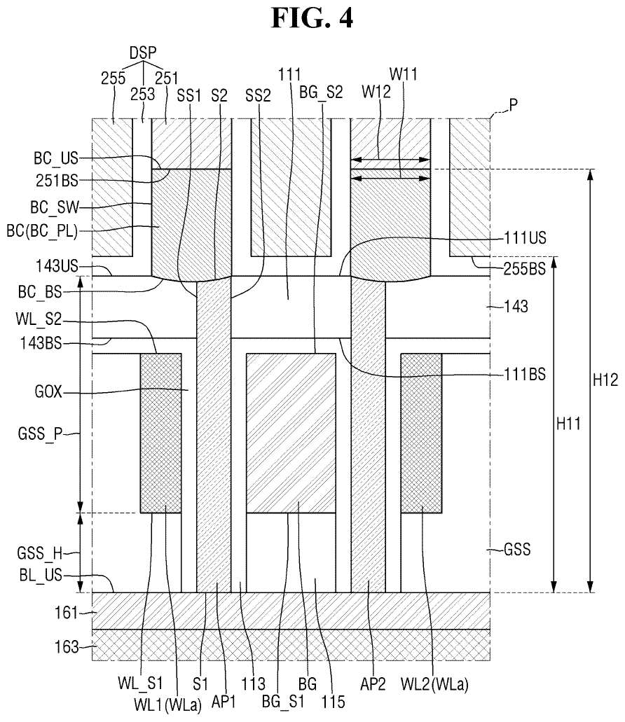

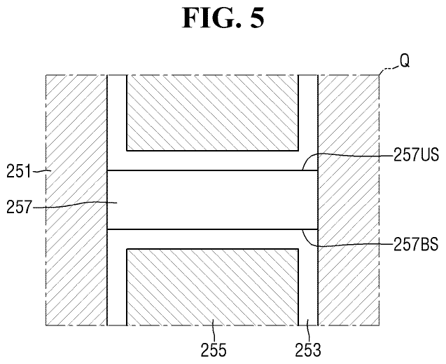

FIG. 1 is a layout diagram for explaining a semiconductor memory device according to some embodiments. FIG. 2 is a cross-sectional view taken along lines A-A and B-B of FIG. 1. FIG. 3 is a cross-sectional view taken along lines C-C and D-D of FIG. 1. FIG. 4 is an enlarged view of a portion P of FIG. 4. FIGS. 5 to 9 are enlarged views of a portion Q of FIG. 2.

The semiconductor memory device according to the embodiments of the present invention may include memory cells including a vertical channel transistor (VCT).

Referring to FIGS. 1 to 9, the semiconductor memory device according to some embodiments may include bit lines BL, word lines WL1 and WL2, back gate electrodes BG, a shielding conductive pattern SL, active patterns AP1 and AP2, contact structures BC, and data storage patterns DSP.

The substrate 100 may be a silicon substrate or may include other materials, for example, but not limited to, silicon germanium, indium antimonide, lead telluride, indium arsenide, indium phosphide, gallium arsenide or gallium antimonide.

The substrate 100 may include an upper side 100US. The element isolation film 101 may be disposed inside the substrate 100. The element isolation film 101 may define an active region inside the substrate 100. The element isolation film 101 includes an insulating material.

The substrate 100 may include a cell array region in which a data storage pattern DSP is disposed, and a peripheral circuit region defined around the cell array region.

A peri-gate structure PG may be disposed on the substrate 100. For example, the peri-gate structure PG may be disposed on the upper side 100US of the substrate. The peri-gate structure PG may be disposed over the cell array region and the peripheral circuit region. In other words, a part of the peri-gate structure PG may be disposed in the cell array region of the substrate 100, and the rest of the peri-gate structure PG may be disposed in the peripheral circuit region of the substrate 100.

The peri-gate structure PG may be included in a sensing transistor, a transfer transistor, a drive transistor, and the like. For example, the peri-gate structure PG included in the sensing transistor may be disposed on the cell array region of the substrate 100, but is not limited thereto. It goes without saying that the types of transistors in the peripheral circuit disposed on the cell array region of the substrate 100 may vary depending on the design and layout of the semiconductor memory device.

The peri-gate structure PG may include a peri-gate insulating film 215, a peri-lower conductive pattern 223, and a peri-upper conductive pattern 225. The peri-gate insulating film 215 may include a silicon oxide film, a silicon oxynitride film, a high dielectric constant insulating film having a higher dielectric constant than a silicon oxide film, or a combination thereof. The high dielectric constant insulating film may include, for example, but not limited to, at least one of metal oxide, metal oxynitride, metal silicon oxide, and/or metal silicon oxynitride.

The peri-lower conductive pattern 223 and the peri-upper conductive pattern 225 each include a conductive material. For example, the peri-lower conductive pattern 223 and the peri-upper conductive pattern 225 may each include at least one of a doped semiconductor material, conductive metal nitride, conductive metal silicon nitride, metal carbonitride, conductive metal silicide, conductive metal oxide, two-dimensional (2D) material, and metal. In the semiconductor device according to some embodiments, the two-dimensional material may be a metallic material and/or a semiconductor material. The 2D material may include a 2D allotrope or a 2D compound, and may include, but not limited to, at least one of graphene, molybdenum disulfide (MoS₂), molybdenum diselenide (MoSe₂), tungsten diselenide (WSe₂), and/or tungsten disulfide (WS₂). That is, since the above-mentioned 2D materials are only listed as an example, the 2D materials that may be included in the semiconductor memory device of the present invention are not limited by the above-mentioned materials. Although the peri-gate structure PG is shown to include a plurality of conductive patterns, the embodiment is not limited thereto.

Although it is not shown, the peri-gate structure PG may further include a peri-gate mask pattern disposed on the peri-upper conductive pattern 225. The peri-gate mask pattern is made up of an insulating material.

A first peri-lower insulating film 227 and a second peri-lower insulating film 228 are disposed on the upper side 100US of the substrate. The first peri-lower insulating film 227 and the second peri-lower insulating film 228 each include an insulating material.

A peri-contact plug 241a and a peri-wiring line 241b may be disposed in or extend into the first peri-lower insulating film 227 and the second peri-lower insulating film 228. The peri-contact plug 241a and the peri-wiring line 241b may be connected to the peri-lower conductive pattern 223 and the peri-upper conductive pattern 225 of the peri-gate structure PG. Although not shown, the peri-contact plug 241a and the peri-wiring line 241b may be connected to a source/drain region disposed on at least one side of the peri-gate structure PG.

Although the peri-contact plug 241a and the peri-wiring line 241b are shown as being different films from each other, the present invention is not limited thereto. A boundary between the peri-contact plug 241a and the peri-wiring line 241b may not be distinguished. The peri-contact plug 241a and the peri-wiring line 241b each include a conductive material.

The first peri-upper insulating film 261 and the second peri-upper insulating film 262 may be disposed on the peri-contact plug 241a and the peri-wiring line 241b. The first peri-upper insulating film 261 and the second peri-upper insulating film 262 each include an insulating material. It goes without saying that, unlike the shown example, an insulating film formed of a single film may be disposed on the peri-contact plug 241a and the peri-wiring line 241b.

The peri-connecting structures 242a and 242b may be connected to the peri-wiring line 241b. The peri-connecting structures 242a and 242b may include a peri-connecting via 242a and a peri-connecting wiring 242b. The peri-connecting via 242a and the peri-connecting wiring 242b each include a conductive material.

Although the peri-connecting via 242a and the peri-connecting wiring 242b are shown as being different films from each other, the present invention is not limited thereto. Although the peri-connecting structures 242a and 242b are shown to include one peri-connecting wiring 242b disposed on one metal level, this is only for convenience of explanation, and embodiments are not limited thereto. The peri-connecting structures 242a and 242b may include a plurality of peri-connecting wirings 242b disposed on different metal levels from each other.

A third peri-upper insulating film 265 may be disposed on the peri-connecting structures 242a and 242b. The third peri-upper insulating film 265 includes an insulating material.

The shielding structures 171, SL and 175 may be disposed on the peri-gate structure PG on the substrate 100. For example, the shielding structures 171, SL and 175 may be disposed on the peri-connecting structures 242a and 242b.

The shielding structures 171, SL, and 175 may include a shielding conductive patterns SL and shielding insulating films 171 and 175. For example, the shielding insulating films 171 and 175 may include a shielding insulating liner 171 and a shielding insulating capping film 175.

The shielding conductive pattern SL may include a plurality of shielding conductive line patterns SLp. Each shielding conductive line pattern SLp may extend in the second direction D2. Each shielding conductive line pattern SLp may be adjacent to each other in the first direction D1. For example, the first direction D1 and the second direction D2 may be horizontal directions that are horizontal to the substrate 100.

Each shielding conductive line pattern SLp may extend from the cell array region to the peripheral circuit region. An end part of the shielding conductive line SL may be disposed on the peripheral circuit region.

The shielding conductive pattern SL includes a conductive material. The shielding conductive pattern SL may include, for example, at least one of a conductive metal nitride, a conductive metal silicon nitride, a metal carbonitride, a conductive metal silicide, a conductive metal oxide, a two-dimensional material, and/or a metal.

A shielding insulating capping film 175 may be disposed on the peri-connecting structures 242a and 242b. The shielding insulating capping film 175 may be disposed between the peri-gate structure PG and the shielding conductive pattern SL.

The shielding insulating capping film 175 may be in contact with the shielding conductive pattern SL. In the semiconductor memory device according to some embodiments, the shielding insulating capping film 175 may be in contact with the shielding conductive line pattern SLp.

The shielding insulating capping film 175 may have a linear shape extending in a second direction D2 along the shielding conductive line pattern SLp. Unlike the shown example, the shielding insulating capping film 175 may have a flat plate shape. In other words, the shielding insulating capping film 175 may overlap the shielding conductive line pattern SLp and the bit line BL in a third direction D3. For example, the third direction D3 may be a vertical direction perpendicular to the substrate 100.

The shielding insulating liner 171 may be disposed on the shielding conductive pattern SL. The shielding insulating liner 171 may extend along the profile of the shielding conductive line pattern SLp.

The shielding insulating liner 171 may be disposed on the bit line BL and the third peri-upper insulating film 265. Unlike the shown example, the shielding insulating liner 171 may not be disposed between the bit line BL and the third peri-upper insulating film 265. In this case, the bit line BL may be in contact with the third peri-upper insulating film 265.

The shielding insulating liner 171 and the shielding insulating capping film 175 may each be made of an insulating material. When the shielding insulating liner 171 and the shielding insulating capping film 175 include the same material, a boundary between the shielding insulating liner 171 and the shielding insulating capping film 175 may not be distinguished.

Because the shielding structures 171, SL, and 175 are disposed between bit lines BL adjacent in the first direction D1, a coupling noise between the bit lines BL may be reduced.

The bit lines BL may be disposed on the peri-gate structure PG on the substrate 100. For example, the bit lines BL may be disposed on the peri-connecting structure 242a and 242b.

The bit line BL may extend long in the second direction D2. The adjacent bit lines BL may be spaced apart in the first direction D1. The bit line BL includes a long side wall extending in the second direction D2, and a short side wall extending in the first direction D1.

The bit line BL may be disposed to be adjacent to the shielding conductive line pattern SLp. The bit line BL may be disposed to be adjacent to the shielding conductive line pattern SLp in the first direction D1. In other words, the shielding conductive line pattern SLp may extend in the second direction D2 along the long side wall of the bit line BL.

The bit line BL may be disposed between the shielding conductive line patterns SLp adjacent in the first direction D1. The bit line BL may be disposed on the shielding insulating liner 171. For example, the shielding insulating liner 171 may be in contact with the bit line BL.

Although not shown, each bit line BL may extend from the cell array region to the peripheral circuit region. The end part of each bit line BL may be disposed on the peripheral circuit region.

Each bit line BL may include a semiconductor pattern 161, a metal pattern 163, and a bit line mask pattern 165 that are stacked in order. Unlike the shown example, the bit line BL may include one of a semiconductor pattern 161 and/or a metal pattern 163.

The bit line BL may include a conductive bit line. The conductive bit line includes a film made of a conductive material among the bit lines BL. The conductive bit line may include the semiconductor pattern 161 and the metal pattern 163.

The semiconductor pattern 161 may include a conductive semiconductor material. The conductive semiconductor material may be, for example, a semiconductor material doped with impurities. The semiconductor pattern 161 may include at least one of polysilicon, polysilicon germanium, polygermanium, amorphous silicon, amorphous silicon germanium, and/or amorphous germanium.

The metal pattern 163 may include a conductive material including metal. The metal pattern 163 may include, for example, at least one of a conductive metal nitride, a conductive metal silicon nitride, a metal carbonitride, a conductive metal silicide, a conductive metal oxide, a two-dimensional material, and/or a metal.

The bit line mask pattern 165 may include an insulating material. The bit line mask pattern 165 may include, but not limited to, silicon nitride, silicon oxynitride or the like.

The first active patterns AP1 and the second active patterns AP2 may be disposed on the respective bit lines BL. The first active patterns AP1 and the second active patterns AP2 may be alternately arranged along the second direction D2.

The first active patterns AP1 may be spaced apart from each other in the first direction D1. The first active patterns AP1 may be spaced apart at regular intervals. The second active patterns AP2 may be spaced apart from each other in the first direction D1. The second active patterns AP2 may be spaced apart at regular intervals. The first active pattern AP1 may be spaced apart from the second active pattern AP2 in the second direction D2. The first active patterns AP1 and the second active patterns AP2 may be arranged two-dimensionally along the first direction D1 and the second direction D2 that intersect each other.

For example, the first active pattern AP1 and the second active pattern AP2 may each be formed of a single crystal semiconductor material. As an example, the first active pattern AP1 and the second active pattern AP2 may each be formed of single crystal silicon.

The first active pattern AP1 and the second active pattern AP2 may each have a length in the first direction D1, a width in the second direction D2, and a height in the third direction D3. Each of the first active pattern AP1 and the second active pattern AP2 may have a substantially uniform width. That is, each of the first active pattern AP1 and the second active pattern AP2 may have substantially the same width on the first and second surfaces S1 and S2. Further, the width of the first active pattern AP1 may be equal to the width of the second active pattern AP2.

The width of the first active pattern AP1 and the width of the second active pattern AP2 may range from several nm to several tens of nm. For example, the width of the first active pattern AP1 and the width of the second active pattern AP2 may be, but not limited to, 1 nm to 30 nm, more preferably 1 nm to 10 nm. The lengths of each of the first and second active patterns AP1 and AP2 may be greater than the line width of the bit line BL. That is, the lengths of each of the first and second active patterns AP1 and AP2 may be greater than the width of the bit line BL in the first direction D1.

In FIG. 4, each of the first active pattern AP1 and the second active pattern AP2 includes a first surface S1 and a second surface S2 that are opposite to each other in the third direction D3. For example, the first surfaces S1 of the first and second active patterns AP1 and AP2 looks at or faces the bit line BL. The second surfaces S2 of the first and second active patterns AP1 and AP2 look at or face the contact pattern BC.

The first surfaces S1 of the first and second active patterns AP1 and AP2 are electrically and/or physically connected to the bit line BL. For example, the first surfaces S1 of the first and second active patterns AP1 and AP2 may be electrically and/or physically connected to the semiconductor pattern 161 of the bit line BL. Unlike the shown example, when the semiconductor pattern 161 is omitted, the first surfaces S1 of the first and second active patterns AP1 and AP2 may be electrically and/or physically connected to the metal pattern 163. The second surfaces S2 of the first and second active patterns AP1 and AP2 may be electrically and/or physically connected to the contact patterns BC.

Each of the first active pattern AP1 and the second active pattern AP2 may include a first side wall SS1 and a second side wall SS2 that are opposite to each other in the second direction D2. The second side wall SS2 of the first active pattern AP1 may face the first side wall SS1 of the second active pattern AP2.

The first side wall SS1 of the first active pattern AP1 may be adjacent to the first word line WL1. The second side wall SS2 of the second active pattern AP2 may be adjacent to the second word line WL2.

Although not shown, as an example, each of the first active pattern AP1 and the second active pattern AP2 may include a first dopant region adjacent to the bit line BL, and a second dopant region adjacent to the contact pattern BC. Each of the first active pattern AP1 and the second active pattern AP2 may include a channel region between the first dopant region and the second dopant region. The first dopant region and the second dopant region are regions doped with a dopant in the first active pattern AP1 and the second active pattern AP2. Unlike the aforementioned example, each of the first active pattern AP1 and the second active pattern AP2 may not include at least one of the first dopant region and the second dopant region.

At the time of operation of the semiconductor memory device, the channel region of the first and second active patterns AP1 and AP2 may be controlled by the first and second word lines WL1 and WL2 and the back gate electrodes BG. Since the first and second active patterns AP1 and AP2 are made of a single crystal semiconductor material, leakage current characteristics of the semiconductor memory device may be improved.

The back gate electrodes BG may be disposed on the bit line BL and the shielding conductive pattern SL. The back gate electrodes BG may be spaced apart from each other in the second direction D2. The back gate electrodes BG may be spaced apart at regular intervals. Each back gate electrode BG may extend in the first direction D1 across the bit line BL.

Each back gate electrode BG may be disposed between a first active pattern AP1 and a second active pattern AP2 that are adjacent to each other in the second direction D2. That is, the first active pattern AP1 may be disposed on one side of each back gate electrode BG, and the second active pattern AP2 may be disposed on the other side of each back gate electrode BG. The height of the back gate electrode BG in the third direction D3 may be smaller than or less than the heights of the first and second active patterns AP1 and AP2.

Each back gate electrode BG may be disposed between the second side wall SS2 of the first active pattern AP1 and the first side wall SS1 of the second active pattern AP2. Each back gate electrode BG may be disposed on the second side wall SS2 of the first active pattern AP1 and the first side wall SS1 of the second active pattern AP2.

The first active pattern AP1 may be disposed between the first word line WL1 and the back gate electrode BG. The second active pattern AP2 may be disposed between the second word line WL2 and the back gate electrode BG. A pair of first word line WL1 and second word line WL2 may be disposed between the back gate electrodes BG adjacent to each other in the second direction D2.

The back gate electrode BG may include a first surface BG_S1 and a second surface BG_S2 that are opposite to each other in the third direction D3. The first surface BG_S1 of the back gate electrode is closer to the bit line BL than the second surface BG_S2 of the back gate electrode.

The back gate electrode BG may include a first surface BG_S1 and a second surface BG_S2 that are opposite to each other in the third direction D3. The first surface BG_S1 of the back gate electrode is closer to the bit line BL than the second surface BG_S2 of the back gate electrode. The first surface BG_S1 of the back gate electrode may look at or face the bit line BL.

The back gate electrode BG includes a conductive material, and may include, for example, at least one of a conductive semiconductor material, conductive metal nitride, conductive metal silicon nitride, metal carbonitride, conductive metal silicide, conductive metal oxide, a two-dimension material, and/or a metal.

A voltage is applied to the back gate electrode BG at the time of operation of the semiconductor memory device, and the threshold voltage of the vertical channel transistor may be adjusted. The threshold voltage of the vertical channel transistor is adjusted, and leakage current characteristics may be prevented from deteriorating.

A back gate capping pattern 111 may be disposed between the first active pattern AP1 and the second active pattern AP2 adjacent to each other in the second direction D2. The back gate capping pattern 111 may extend in the first direction D1 along with the back gate electrode BG. The back gate capping pattern 111 may be disposed on the second surface BG_S2 of the back gate electrode.

The back gate capping pattern 111 may include a bottom surface 111BS and an upper surface 111US that are opposite to each other in the third direction D3. The bottom surface 111BS of the back gate capping pattern may look at or face the back gate electrode BG.

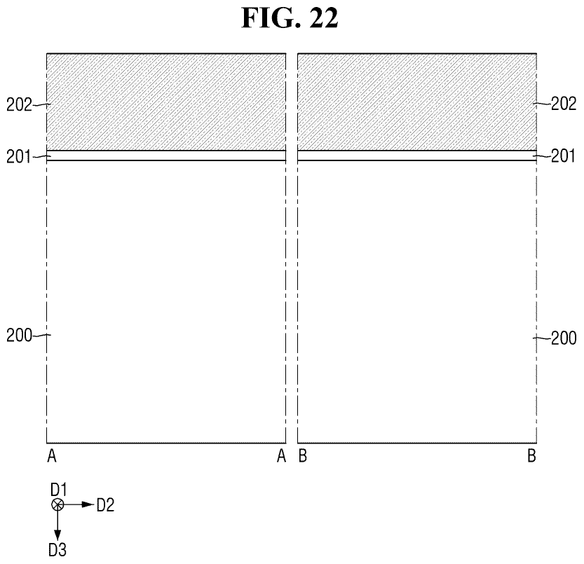

The back gate capping pattern 111 may be made of an insulating material. The back gate capping pattern 111 may include, for example, at least one of a silicon oxide film, a silicon oxynitride film, and/or a silicon nitride film. For example, the back gate capping pattern 111 may have an etching selectivity with respect to the buried insulating layer (201 of FIG. 22).

The back gate insulating pattern 113 may be disposed between the back gate electrode BG and the first active pattern AP1, and between the back gate electrode BG and the second active pattern AP2. The back gate insulating pattern 113 may be disposed between the back gate capping pattern 111 and the back gate electrode BG. The back gate insulating pattern 113 may extend along the second surface BG_S2 of the back gate electrode.

When the back gate insulating pattern 113 is formed earlier than the back gate capping pattern 111, a shape different from that of the back gate insulating pattern 113 shown in FIGS. 2 to 4 may be shown. The back gate insulating pattern 113 may not extend along the second surface BG_S2 of the back gate electrode. The back gate insulating pattern 113 may be disposed between the back gate capping pattern 111 and the first active pattern AP1, and between the back gate capping pattern 111 and the second active pattern AP2.

The back gate insulating pattern 113 may be made of an insulating material. The back gate insulating pattern 113 may include, for example, a silicon oxide film, a silicon oxynitride film, a high dielectric constant insulating film having a higher dielectric constant than a silicon oxide film, or a combination thereof.

A back gate separation pattern 115 may be disposed between the bit line BL and the back gate electrode BG. The back gate separation pattern 115 may be disposed between the first active pattern AP1 and the second active pattern AP2 adjacent to each other in the second direction D2.

In the back gate separation pattern 115, the bit line BL may extend in the first direction D1 along with the back gate electrode BG. In the back gate separation pattern 115, the bit line BL may be disposed on the first surface BG_S1 of the back gate electrode. A thickness of the back gate separation pattern 115 between the bit lines BL may be different from a thickness of the back gate separation pattern 115 on the bit line BL, but the embodiment is not limited thereto.

The back gate separation pattern 115 may be made of an insulating material. The back gate separation pattern 115 may include, for example, but not limited to, at least one of a silicon oxide film, a silicon oxynitride film, and/or a silicon nitride film.

The first word line WL1 and the second word line WL2 may be disposed on the bit line BL and the shielding conductive pattern SL. Each of the first word line WL1 and the second word line WL2 may extend in the first direction D1. The first word line WL1 and the second word line WL2 may be alternately arranged in the second direction D2.

The first word line WL1 may be disposed on the first side wall SS1 of the first active pattern AP1. The second word line WL2 may be disposed on the second side wall SS2 of the second active pattern AP2. The first active patterns AP1 and the second active patterns AP2 may be disposed between the first word line WL1 and the second word line WL2 adjacent to each other in the second direction D2.

The first word line WL1 and the second word line WL2 may be spaced apart from the bit line BL and the contact pattern BC in the third direction D3. The first word line WL1 and the second word line WL2 may be located between the bit line BL and the contact pattern BC.

Each of the first word line WL1 and the second word line WL2 may have a width in the second direction D2. The width of the first word line WL1 and the width of the second word line WL2 on the bit line BL may be different from the width of the first word line WL1 and the width of the second word line WL2 on the shielding conductive line SL.

For example, each of the first word line WL1 and the second word line WL2 may include a first portion WLa of the word line and a second portion WLb of the word line. The width of the first portion WLa of the word line in the second direction D2 may be smaller than or less than the width of the second portion WLb of the word line in the second direction D2. As an example, the first portion WLa of the word line may be disposed on the bit line BL. The second portion WLb of the word line may be disposed on the shielding conductive line SL.

Each of the first word line WL1 and the second word line WL2 may include the first portion WLa of the word line and the second portion WLb of the word line that are alternately arranged along the first direction D1. In the first word line WL1, each first active pattern AP1 may be disposed between the second portions WLb of the word lines adjacent in the first direction D1. In the second word line WL2, each second active pattern AP2 may be disposed between the second portions WLb of word lines adjacent in the first direction D1.

Unlike the shown example, the width of the first portion WLa of the word line in the second direction D2 may be the same as the width of the second portion WLb of the word line in the second direction D2.

The first word line WL1 and the second word line WL2 may include a first surface WL_S1 and a second surface WL_S2 that are opposite to each other in the third direction D3. The first surface WL_S1 of the first and second word lines is closer to the bit line BL than the second surface WL_S2 of the first and second word lines. The first surface WL_S1 of the first and second word lines look at or face the bit line BL.

The first word line WL1 will be explained as an example. As an example, the height of the first word line WL1 in the third direction D3 may be equal to the height of the back gate electrode BG in the third direction D3. As another example, the height of the first word line WL1 in the third direction D3 may be greater than the height of the back gate electrode BG in the third direction D3. As yet another example, the height of the first word line WL1 in the third direction D3 may be smaller than or less than the height of the back gate electrode BG in the third direction D3.

Further, as an example, the height of the first surface WL_S1 of the first word line may be equal to the height of the first surface BG_S1 of the back gate electrode on the basis of the upper surface BL_US of the bit line. As another example, the first surface WL_S1 of the first word line may be higher than the first surface BG_S1 of the back gate electrode. As yet another example, the first surface WL_S1 of the first word line may be lower than the first surface BG_S1 of the back gate electrode.

In addition, as an example, the height of the second surface WL_S2 of the first word line may be equal to the height of the second surface BG_S2 of the back gate electrode on the basis of the upper surface BL_US of the bit line. As another example, the second surface WL_S2 of the first word line may be higher than the second surface BG_S2 of the back gate electrode. As yet another example, the second surface WL_S2 of the first word line may be lower than the second surface BG_S2 of the back gate electrode.

The first word line WL1 and the second word line WL2 may include a conductive material. The first word line WL1 and the second word line WL2 may include, for example, at least one of doped polysilicon, conductive metal nitride, conductive metal silicon nitride, metal carbonitride, conductive metal silicide, conductive metal oxide, a two-dimensional material, and/or a metal.

The first surfaces WL_S1 of the first and second word lines WL1 and WL2 may be a plane. Unlike the shown example, as an example, the first surfaces WL_S1 of the first and second word lines WL1 and WL2 may be concavely rounded. As another example, each of the first word line WL1 and the second word line WL2 may have the form of a spacer. In other words, the first surfaces WL_S1 of the first and second word lines WL1 and WL2 may be convexly rounded.

The second surface WL_S2 of the first and second word lines WL1 and WL2 may be a plane. Unlike the shown example, the second surface WL_S2 of the first and second word lines WL1 and WL2 may have a concavely curved surface. Although the first surface BG_S1 of the back gate electrode and the second surface BG_S2 of the back gate electrode are shown as being a plane, the embodiments are not limited thereto.

Gate insulating patterns GOX may be disposed between the first word line WL1 and the first active pattern AP1, and between the second word line WL2 and the second active pattern AP2. The gate insulating pattern GOX may extend in the first direction D1 along with the first word line WL1 and the second word line WL2.

The gate insulating pattern GOX may include a silicon oxide film, a silicon oxynitride film, a high dielectric constant insulating film having a higher dielectric constant than a silicon oxide film, or a combination thereof.

The gate insulating pattern GOX may extend along the first side wall SS1 of the first active pattern AP1, and may extend along the second side wall SS2 of the second active pattern AP2. The gate insulating pattern GOX may not be disposed between the first active pattern AP1 and a gate capping pattern 143, and between the second active pattern AP2 and the gate capping pattern 143. From the viewpoint of the cross-sectional view, the gate insulating pattern GOX between the first active pattern AP1 and the first word line WL1 may be physically connected to the gate insulating pattern GOX between the second active pattern AP2 and the second word line WL2.

Unlike the shown example, the gate insulating pattern GOX between the first active pattern AP1 and the first word line WL1 may be separated from the gate insulating pattern GOX between the second active pattern AP2 and the second word line WL2.

The gate capping pattern 143 may be disposed between the first word line WL1 and the contact pattern BC, and between the second word line WL2 and the contact pattern BC. The gate capping pattern 143 may cover, overlap, or be on the second surface WL_S2 of the first and second word lines WL1 and WL2. The gate capping pattern 143 may be a word line capping pattern.

The gate capping pattern 143 may include a bottom surface 143BS and an upper surface 143US that are opposite to each other in the third direction D3. The bottom surface 143BS of the gate capping pattern may overlap the first word line WL1 and the second word line WL2.

The gate insulating pattern GOX may extend along the bottom surface 143BS of the gate capping pattern. The gate insulating pattern GOX may be disposed between the bottom surface 143BS of the gate capping pattern and the second surface WL_S2 of the first word line, and between the bottom surface 143BS of the gate capping pattern and the second surface WL_S2 of the second word line.

When the gate insulating pattern GOX is formed earlier than the gate capping pattern 143, a shape different from that of the gate insulating pattern GOX shown in FIGS. 2 to 4 may be shown. The gate insulating pattern GOX may not extend along the bottom surface 143BS of the gate capping pattern. The gate insulating pattern GOX may be disposed between the first active pattern AP1 and the first word line WL1, and between the second active pattern AP2 and the second word line WL2. The gate insulating pattern GOX may not be disposed between the bottom surface 143BS of the gate capping pattern and the second surface WL_S2 of the first word line, and between the bottom surface 143BS of the gate capping pattern and the second surface WL_S2 of the second word line. As an example, the gate insulating pattern GOX may extend along the upper surface 143US of the gate capping pattern. The gate insulating film GOX on the upper surface 143US of the gate capping pattern may not be removed during the formation of the contact pattern BC and the storage electrode 251. As another example, the gate insulating pattern GOX may not extend along the upper surface 143US of the gate capping pattern. The gate insulating film GOX on the upper surface 143US of the gate capping pattern may be removed during the formation of the contact pattern BC and the storage electrode 251.

The gate capping pattern 143 may include, for example, at least one of a silicon oxide film, a silicon oxynitride film, and/or a silicon nitride film. Unlike the shown example, the gate capping pattern 143 may include a plurality of insulating films.

The gate separation pattern GSS may be disposed on the bit line BL. The gate separation pattern GSS may be disposed between the bit line BL and the contact pattern BC. The gate separation pattern GSS may be in contact with the bit line BL.

The gate separation pattern GSS may be disposed between the first word line WL1 and the second word line WL2 adjacent to each other in the second direction D2. The first word line WL1 and the second word line WL2 may be separated by the gate separation pattern GSS. The gate separation pattern GSS may extend in the first direction D1 between the first word line WL1 and the second word line WL2.

The first word line WL1 may be disposed between the gate separation pattern GSS and the first active pattern AP1. The second word line WL2 may be disposed between the gate separation pattern GSS and the second active pattern AP2.

The gate separation pattern GSS may include a horizontal portion GSS_H and a protruding portion GSS_P. The protruding portion GSS_P of the gate separation pattern may protrude from the horizontal portion GSS_H of the gate separation pattern in the third direction D3.

The horizontal portion GSS_H of the gate separation pattern may be closer to the bit line BL than the protruding portion GSS_P of the gate separation pattern. The horizontal portion GSS_H of the gate separation pattern may be in contact with the bit line BL. The width of the horizontal portion GSS_H of the gate separation pattern in the second direction D2 is greater than the width of the protruding portion GSS_P of the gate separation pattern in the second direction D2.

The protruding portion GSS_P of the gate separation pattern GSS may be disposed between the side wall of the first word line WL1 and the side wall of the second word line WL2 that face each other. The horizontal portion GSS_H of the gate separation pattern GSS may cover, overlap, or be on the first surface WL_S1 of the first and second word lines WL1 and WL2.

The first word line WL1 and the second word line WL2 are disposed on the horizontal portion GSS_H of the gate separation pattern. The first word line WL1 and the second word line WL2 may be in the form of sitting on the horizontal portion GSS_H of the gate separation pattern GSS. The first word line WL1 and the second word line WL2 may be disposed between the horizontal portion GSS_H of the gate separation pattern GSS and the contact pattern BC.

The gate separation pattern GSS may be made of an insulating material. Unlike the shown example, the gate separation pattern GSS may include a plurality of insulating films.

The contact structures BC may be disposed on the first active pattern AP1 and the second active pattern AP2. The contact structures BC may be electrically and/or physically connected to each of the first active pattern AP1 and the second active pattern AP2. The contact structures BC may be electrically and/or physically connected to the second surface S2 of the first and second active patterns AP1 and AP2.

The contact structures BC may protrude in the third direction D3 beyond the upper surface 111US of the back gate capping pattern and the upper surface 143US of the gate capping pattern. From the viewpoint of a plan view, each contact structure BC may have various shapes such as a circle, ellipse, a rectangle, a square, a rhombus, and/or a hexagon.

The contact structure BC may include an upper surface BC_US and a bottom surface BC_BS that are opposite to each other in the third direction D3. The bottom surface BC_BS of the contact structure may be electrically and/or physically connected to or in contact with the first active pattern AP1 and the second active pattern AP2. The bottom surface BC_BS of the contact structure may be electrically and/or physically connected to or in contact with the second surface S2 of the first and second active patterns AP1 and AP2.

The upper surface BC_US of the contact structure may protrude beyond the back gate capping pattern 111 and the gate capping pattern 143 in the third direction D3. On the basis of the upper surface BL_US of the bit line, the upper surface BC_US of the contact structure is higher than the upper surface 111US of the back gate capping pattern and the upper surface 143US of the gate capping pattern.

The contact structure BC may include a side wall BC_SW that electrically and/or physically connects the upper surface BC_US of the contact structure and the bottom surface BC_BS of the contact structure. The side wall BC_SW of the contact structure extends in the third direction D3 from the viewpoint of the cross-sectional view.

The contact structure BC may include a conductive material. The contact structure BC may include a contact plug pattern BC_PL made of a conductive material. The contact plug pattern BC_PL may include, for example, at least one of a conductive semiconductor material, a conductive metal nitride, a conductive metal silicon nitride, a metal carbonitride, a conductive metal silicide, a conductive metal oxide, a two-dimensional material, and/or a metal. Although the contact plug pattern BC_PL is shown as being a single film, this is only for convenience of explanation, and the embodiments are not limited thereto.

In the semiconductor memory device according to some embodiments, the side wall BC_SW of the contact structure may be defined by a contact plug pattern BC_PL. The contact plug pattern BC_PL may include a side wall BC_SW of the contact structure. An upper surface BC_US of the contact structure and a bottom surface BC_BS of the contact structure may be defined by the contact plug pattern BC_PL.

The data storage patterns DSP may be disposed on each of the contact structures BC. The data storage patterns DSP may be disposed on each of the upper surfaces BC_US of the contact structures.

The data storage patterns DSP may be electrically connected to each of the first and second active patterns AP1 and AP2. The data storage patterns DSP may be arranged in the form of a matrix along the first direction D1 and the second direction D2, as shown in FIG. 1.

As an example, the data storage patterns DSP may be capacitors. The data storage patterns DSP may include a capacitor dielectric film 253 interposed between the storage electrodes 251 and a plate electrodes 255. The storage electrode 251 may be a lower electrode of a capacitor. The plate electrode 255 may be an upper electrode of the capacitor.

The storage electrode 251 may extend long in the third direction D3. The storage electrode 251 may have a pillar shape, for example. The storage electrode 251 may be electrically and/or physically connected to the upper surface BC_US of the contact structure.

The storage electrode 251 may include a bottom surface 251BS that looks at or faces the contact structure BC. The bottom surface 251BS of the storage electrode is electrically and/or physically connected to the upper surface BC_US of the contact structure.

For example, a width W12 of the bottom surface 251BS of the storage electrode in the second direction D2 may be equal to a width W11 of the upper surface BC_US of the contact structure in the second direction D2. Although not shown, the width of the bottom surface 251BS of the storage electrode in the first direction D1 may be equal to the width of the upper surface BC_US of the contact structure in the first direction D1.

The capacitor dielectric film 253 may be disposed on the storage electrodes 251. The capacitor dielectric film 253 may extend along the side wall of the storage electrode 251.

The capacitor dielectric film 253 may extend along the side wall BC_SW of the contact structure. For example, the capacitor dielectric film 253 may be in contact with the side wall BC_SW of the contact structure. The capacitor dielectric film 253 may be in contact with the contact plug pattern BC_PL.

The capacitor dielectric film 253 may extend along the upper surface 111US of the back gate capping pattern 111 and the upper surface 143US of the gate capping pattern. The capacitor dielectric film 253 may be in contact with the back gate capping pattern 111 and the gate capping pattern 143. For example, the capacitor dielectric film 253 may be in contact with the upper surface 111US of the back gate capping pattern and the upper surface 143US of the gate capping pattern.

Unlike the shown example, as an example, when the back gate insulating pattern 113 extends along the upper surface 111US of the back gate capping pattern, the capacitor dielectric film 253 may not be in contact with the upper surface 111US of the back gate capping pattern. As another example, when the gate insulating pattern GOX extends along the upper surface 143US of the gate capping pattern, the capacitor dielectric film 253 may not be in contact with the upper surface 143US of the gate capping pattern.

The plate electrode 255 may be disposed on the capacitor dielectric film 253. A part of the plate electrode 255 may protrude toward the substrate 100 beyond the upper surface BS_US of the contact structure.

From the viewpoint of a cross-sectional view, the plate electrode 255 may include a bottom surface 255BS that looks at or faces the bit line BL. A portion of the plate electrode 255 that protrudes toward the substrate 100 beyond the upper surface BS_US of the contact structure may include the bottom surface 255BS of the plate electrode.

On the upper surface BL_US of the bit line, the bottom surface 255BS of the plate electrode is lower than the upper surface BS_US of the contact structure. A height H12 from the upper surface BL_US of the bit line to the upper surface BS_US of the contact structure is greater than a height H11 from the upper surface BL_US of the bit line to the bottom surface 255BS of the plate electrode.

The plate electrode 255 may cover, overlap, or be on at least a part of the side wall BC_SW of the contact structure. In other words, from the viewpoint of the cross-sectional view, the plate electrode 255 may overlap at least a part of the side wall BC_SW of the contact structure in the second direction D2. Although not shown, the plate electrode 255 may overlap at least a part of the side wall BC_SW of the contact structure in the first direction D1.

In the semiconductor memory device according to some embodiments, the plate electrode 255 may cover, overlap, or be on a part of the side wall BC_SW of the contact structure. On the basis of the upper surface BL_US of the bit line, the bottom surface 255BS of the plate electrode may be higher than the bottom surface BC_BS of the contact structure.

The storage electrode 251 and the plate electrode 255 may each include, for example, at least one of a conductive semiconductor material, a conductive metal nitride, a conductive metal silicon nitride, a metal carbonitride, a conductive metal silicide, a conductive metal oxide, and/or a metal. The capacitor dielectric film 253 may include at least one of a ferroelectric material, an antiferroelectric material, and/or a paraelectric material. For example, the capacitor dielectric film 253 may include one of the ferroelectric material, the antiferroelectric material, the paraelectric material, combinations of the ferroelectric material and antiferroelectric material, combinations of the ferroelectric material and paraelectric material, combinations of paraelectric material and antiferroelectric material, and/or combinations of the ferroelectric material, the antiferroelectric material and the paraelectric material.

In contrast, the data storage patterns DSP may be variable resistance patterns that may be switched between two resistance states by electrical pulses applied to the memory element. For example, the data storage patterns DSP may include a phase-change material, perovskite compounds, transition metal oxide, magnetic materials, ferromagnetic materials or antiferromagnetic materials.

At least one or more lower electrode supports 257 and 258 may be disposed on the first active pattern AP1 and the second active pattern AP2. At least one or more lower electrode support 257 and 258 may support the storage electrode 251.

A plurality of lower electrode supports 257 and 258 may be disposed on the first active pattern AP1 and the second active pattern AP2. The plurality of lower electrode supports 257 and 258 include a first lower electrode support 257 and a second lower electrode support 258 that are sequentially disposed on the first active pattern AP1 and the second active pattern AP2. The first lower electrode support 257 and the second lower electrode support 258 may be spaced apart from each other in the third direction D3.

Unlike the shown example, one lower electrode support that supports the storage electrode 251 may be disposed.

The first lower electrode support 257 will be explained as an example. The first lower electrode support 257 may include an upper surface 257US and a bottom surface 257BS that are opposite to each other in the third direction D3. The bottom surface 257BS of the first lower electrode support may look at or face the bit line BL.

In the following description, the shape of the bottom surface 257BS of the first lower electrode support and the shape of the upper surface 257US of the first lower electrode support may be the shape between adjacent storage electrodes 251.

In FIG. 5, the bottom surface 257BS of the first lower electrode support and the upper surface 257US of the first lower electrode support may each be a plane.

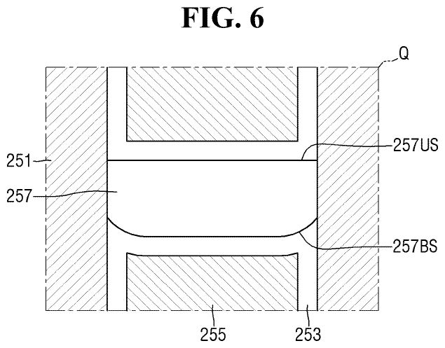

In FIGS. 6 to 9, at least one of the bottom surface 257BS of the first lower electrode support and the upper surface 257US of the first lower electrode support may include a curved surface.

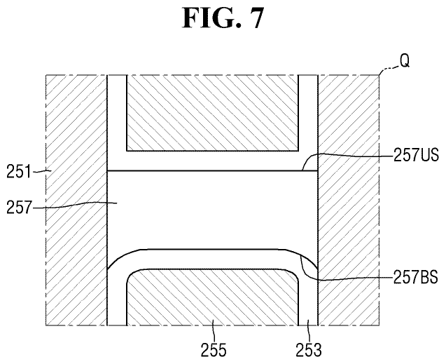

In FIGS. 6 and 7, the upper surface 257US of the first lower electrode support may be a plane. The bottom surface 257BS of the first lower electrode support may include a curved surface. Unlike the shown example, the upper surface 257US of the first lower electrode support may include a curved surface, and the bottom surface 257BS of the first lower electrode support may be a plane.

In FIG. 6, the bottom surface 257BS of the first lower electrode support may include a convexly curved surface. In FIG. 7, the bottom surface 257BS of the first lower electrode support may include a concavely curved surface.

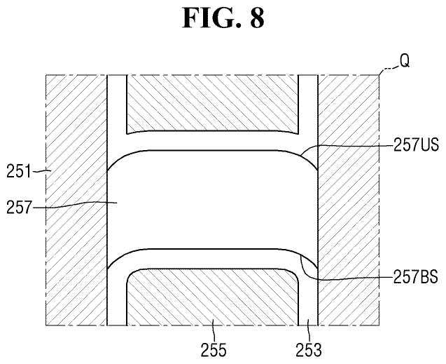

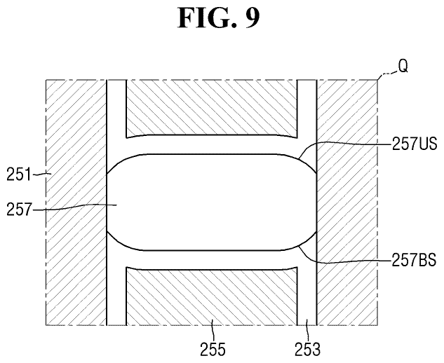

In FIGS. 8 and 9, the bottom surface 257BS of the first lower electrode support and the upper surface 257US of the first lower electrode support may each include a curved surface.

In FIG. 8, the upper surface 257US of the first lower electrode support may include a convexly curved surface. The bottom surface 257BS of the first lower electrode support may include a concavely curved surface. Unlike the shown example, the upper surface 257US of the first lower electrode support may include a concavely curved surface, and the bottom surface 257BS of the first lower electrode support may include a convexly curved surface.

In FIG. 9, the bottom surface 257BS of the first lower electrode support and the upper surface 257US of the first lower electrode support may each include a convexly curved surface. Unlike the shown example, the bottom surface 257BS of the first lower electrode support and the upper surface 257US of the first lower electrode support may each include a concavely curved surface.

The capacitor dielectric film 253 may be disposed on the first lower electrode support 257 and the second lower electrode support 258. The capacitor dielectric film 253 may extend along the bottom surface 257BS of the first lower electrode support and the upper surface 257US of the first lower electrode support. The capacitor dielectric film 253 may extend along the upper surface of the second lower electrode support 258 and the upper surface of the second lower electrode support 258.

Each of the first lower electrode support 257 and the second lower electrode support 258 may include, for example, at least one of silicon nitride, silicon carbonitride, silicon boronitride, silicon carbonate, silicon oxynitride, and/or silicon oxycarbonitride.

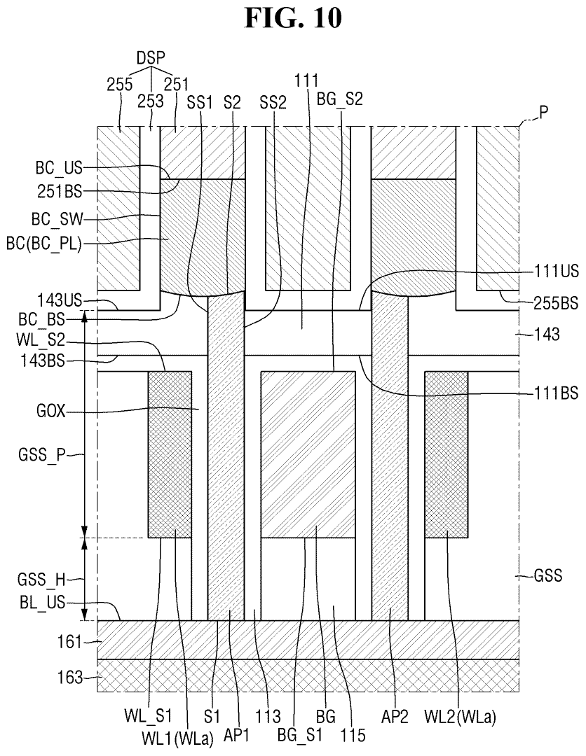

FIGS. 10 to 14 are diagrams for explaining a semiconductor memory device according to some embodiments, respectively. For convenience of explanation, the explanation will focus on points that are different from those explained using FIGS. 1 to 9.

For reference, FIGS. 10 to 14 are enlarged views of a portion P of FIG. 2, respectively.

Referring to FIG. 10, in the semiconductor memory device according to some embodiments, the plate electrode 255 may cover, overlap, or be on the entire side wall BC_SW of the contact structure.

On the basis of the upper surface BL_US of the bit line, the bottom surface 255BS of the plate electrode may be lower than or equal to the lowermost part of the side wall BC_SW of the contact structure.

A part of the capacitor dielectric film 253 may enter or extend into the gate capping pattern 143 and the back gate capping pattern 111.

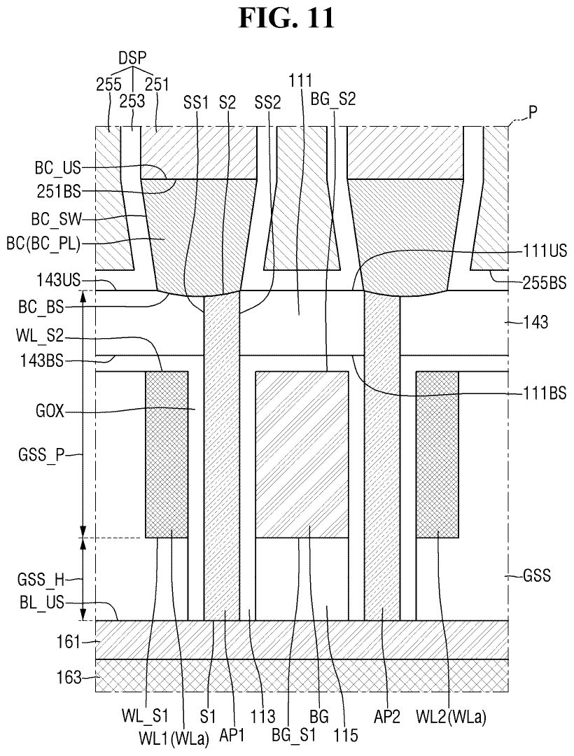

Referring to FIGS. 11 to 13, in the semiconductor memory device according to some embodiments, the width of the contact structure BC may change, as it goes away from the bottom surface BC_BS of the contact structure.

In FIG. 11, the width of the contact structure BC may increase, as it goes away from the bottom surface BC_BS of the contact structure.

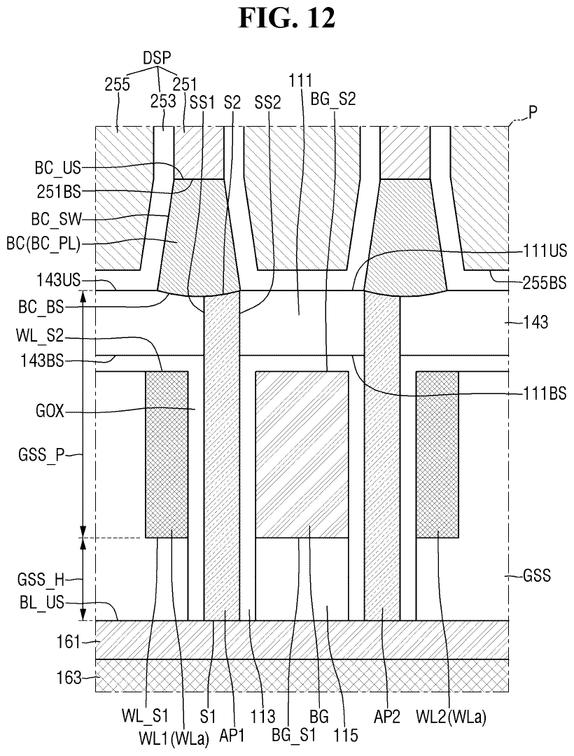

In FIG. 12, the width of the contact structure BC may decrease, as it goes away from the bottom surface BC_BS of the contact structure.

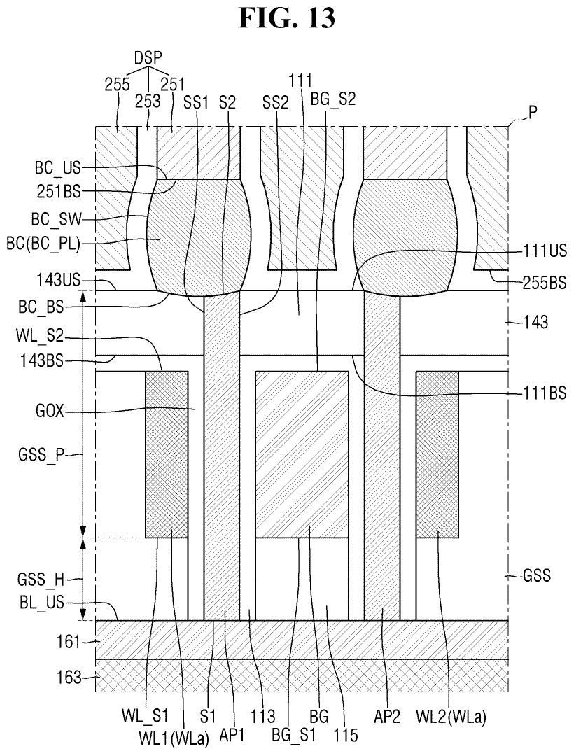

In FIG. 13, the width of the contact structure BC may increase and then decrease, as it goes away from the bottom surface BC_BS of the contact structure.

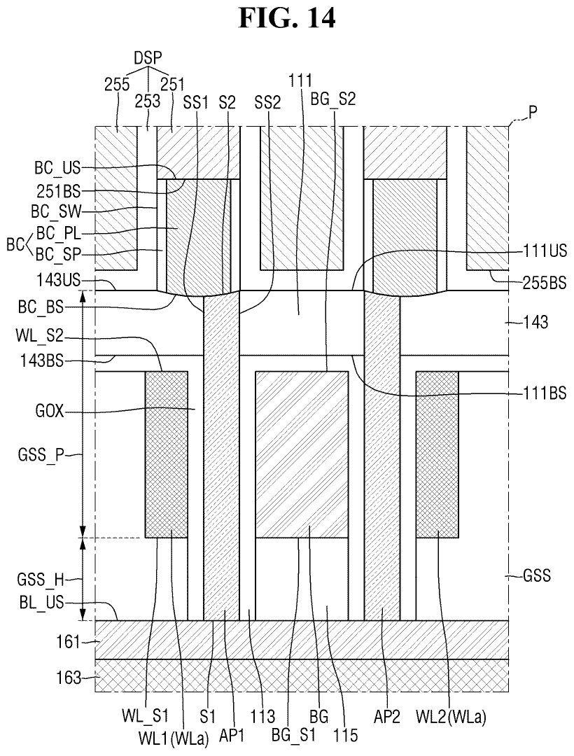

Referring to FIG. 14, in the semiconductor memory device according to some embodiments, the contact structure BC may include a contact plug pattern BC_PL and a contact insulating spacer BC_SP.

The contact insulating spacer BC_SP may extend along a side wall of the contact plug pattern BC_PL. The side wall BC_SW of the contact structure may be defined by the contact insulating spacer BC_SP. The contact insulating spacer BC_SP may include the side wall BC_SW of the contact structure. The capacitor dielectric film 253 extending along the side wall of the contact structure side wall BC_SW may be in contact with the contact insulating spacer BC_SP.

The upper surface BC_US of the contact structure and the bottom surface BC_BS of the contact structure may be defined by the contact plug pattern BC_PL and the contact insulating spacer BC_SP.

The contact insulating spacer BC_SP includes an insulating material. The contact insulating spacer BC_SP may include, for example, but not limited to, at least one of silicon nitride, silicon carbonitride, silicon boronitride, silicon carbonate, silicon oxynitride, and/or silicon oxycarbonitride.

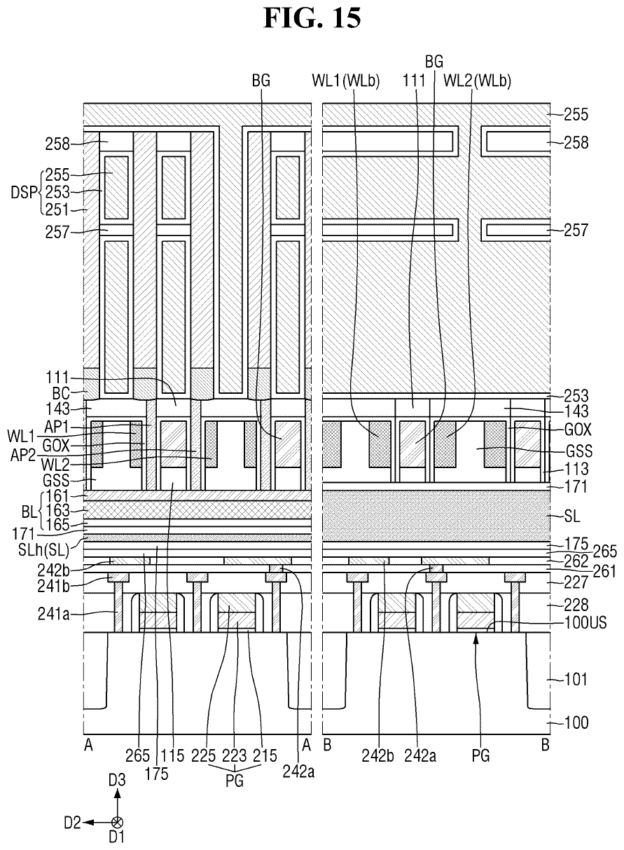

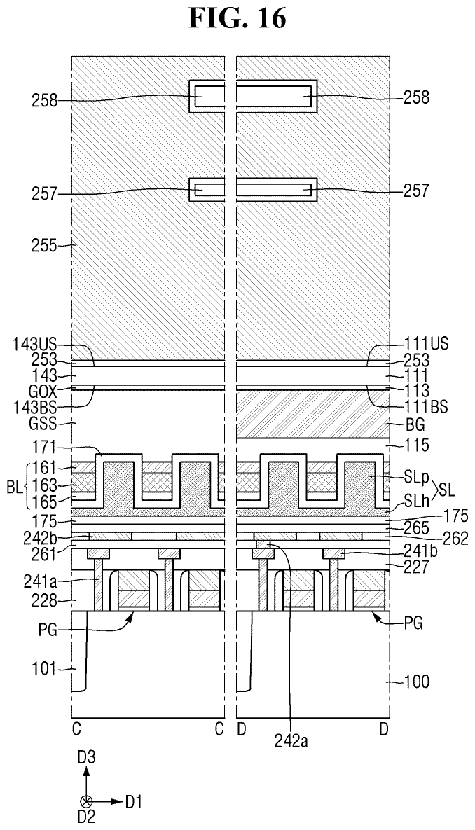

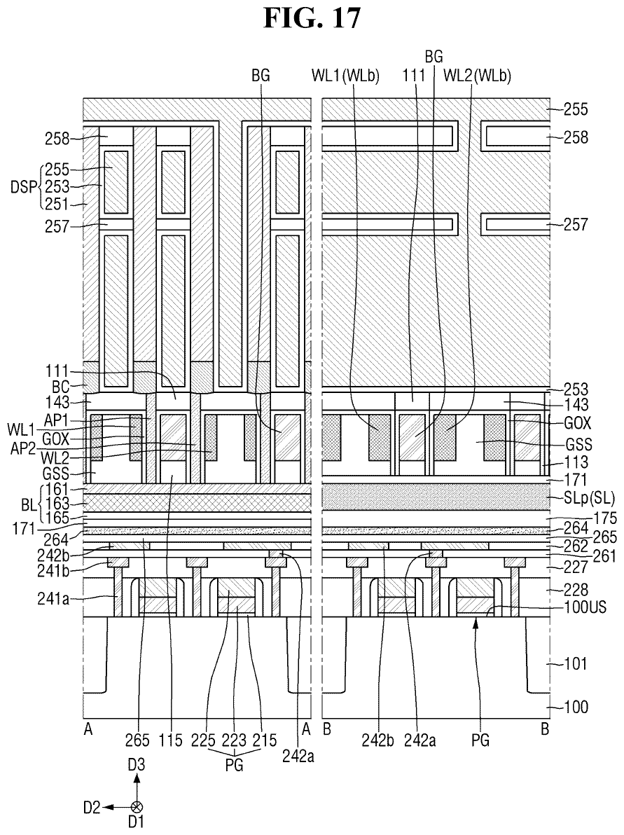

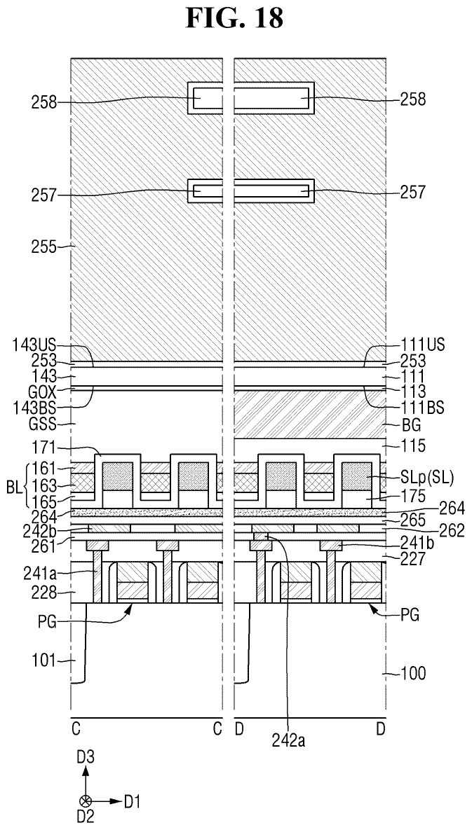

FIGS. 15 and 16 are diagrams for explaining a semiconductor memory device according to some embodiments. FIGS. 17 and 18 are diagrams for explaining a semiconductor memory device according to some embodiments. For convenience of explanation, the explanation will focus on points that are different from those explained using FIGS. 1 to 9.

Referring to FIGS. 15 and 16, in the semiconductor memory device according to some embodiments, the shielding conductive pattern SL may include a shielding conductive plate SLh, and a plurality of shielding conductive line patterns SLp.

The shielding conductive plate SLh may have a flat plate shape. The shielding conductive line pattern SLp may protrude from the shielding conductive plate SLh in the third direction D3. The shielding conductive line pattern SLp is directly connected to the shielding conductive plate SLh.

The shielding insulating liner 171 may extend along the profiles of the shielding conductive plate SLh and the shielding conductive line pattern SLp.

The shielding insulating capping film 175 may be disposed between the shielding conductive plate SLh and the peri-connecting structures 242a and 242b. The shielding insulating capping film 175 may be in contact with the shielding conductive plate SLh.

The bit line BL may be disposed on the shielding conductive pattern SL. The bit line BL may be disposed on the shielding conductive plate SLh.

Referring to FIGS. 17 and 18, the semiconductor memory device according to some embodiments may further include a bonding insulating film 264 disposed between the peri-connecting structures 242a and 242b and the shielding structures SL, 171 and 175.

The bonding insulating film 264 may include, for example, silicon carbonitride (SiCN).

Unlike the shown example, the third peri-upper insulating film 265 may not be disposed on the peri-connecting wiring 242b.

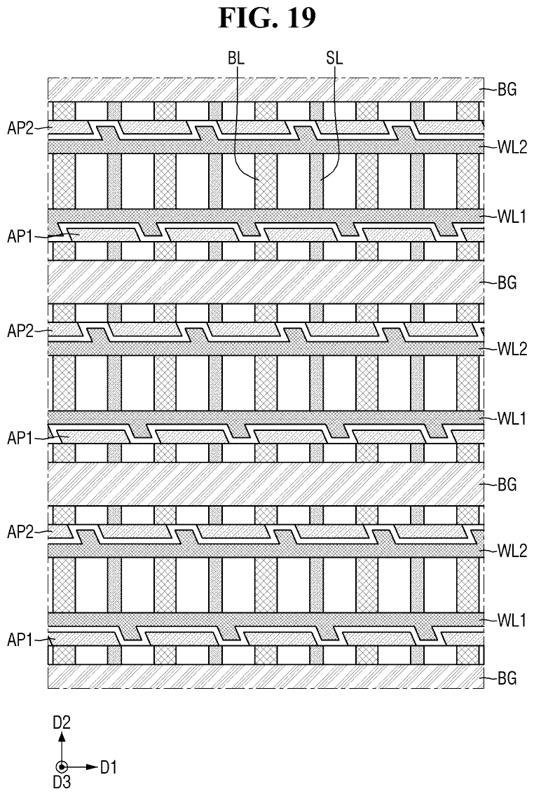

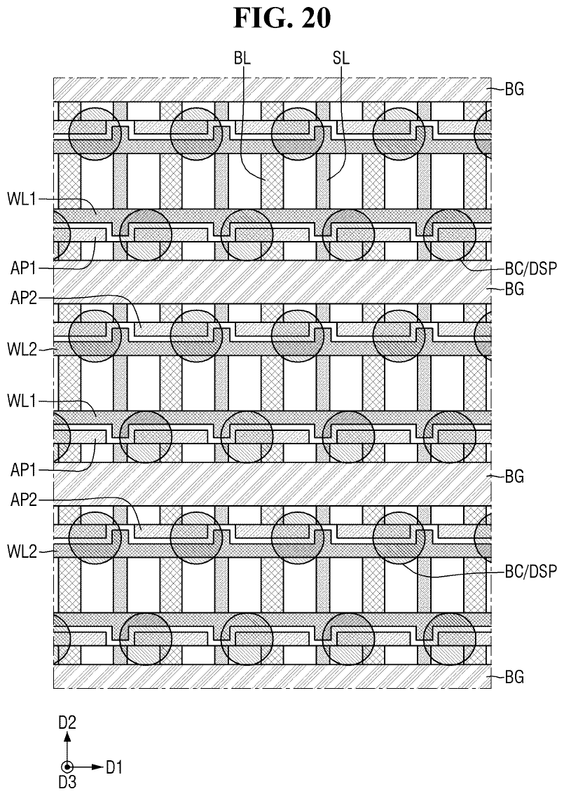

FIGS. 19 and 20 are diagrams for explaining a semiconductor memory device according to some embodiments, respectively. For convenience of explanation, the explanation will focus on the points that are different from those explained using FIGS. 1 to 18.

Referring to FIG. 19, in the semiconductor memory device according to some embodiments, the first and second active patterns AP1 and AP2 may be arranged alternately in a diagonal direction with respect to the first direction D1 and the second direction D2.

From viewpoint of a plan view, each of the first and second active patterns AP1 and AP2 may have a parallelogram shape or a rhombus shape. Since the first and second active patterns AP1 and AP2 are disposed in the diagonal direction, coupling between the first and second active patterns AP1 and AP2 facing each other in the second direction D2 may be reduced.

Referring to FIG. 20, in the semiconductor memory device according to some embodiments, the contact structures BC and the data storage patterns DSP may be disposed in a zigzag shape or a honeycomb shape from the viewpoint of a plan view.

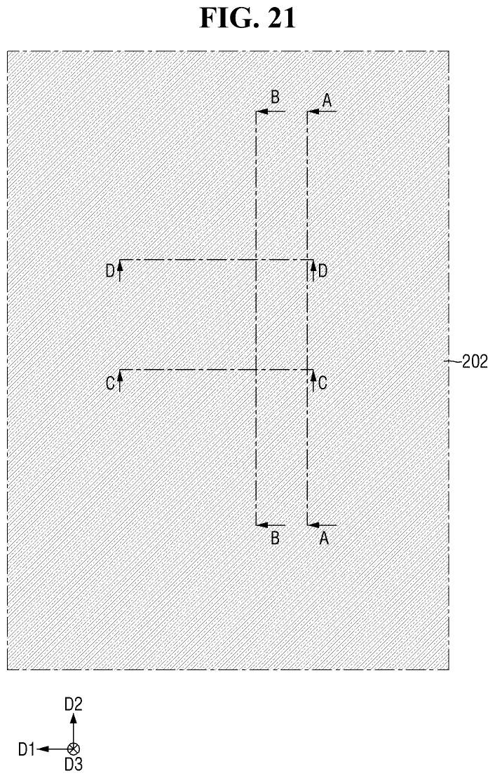

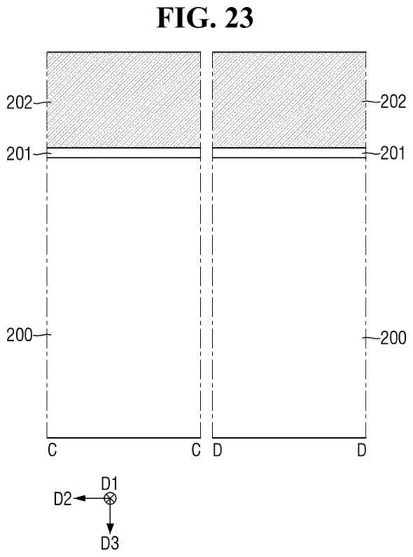

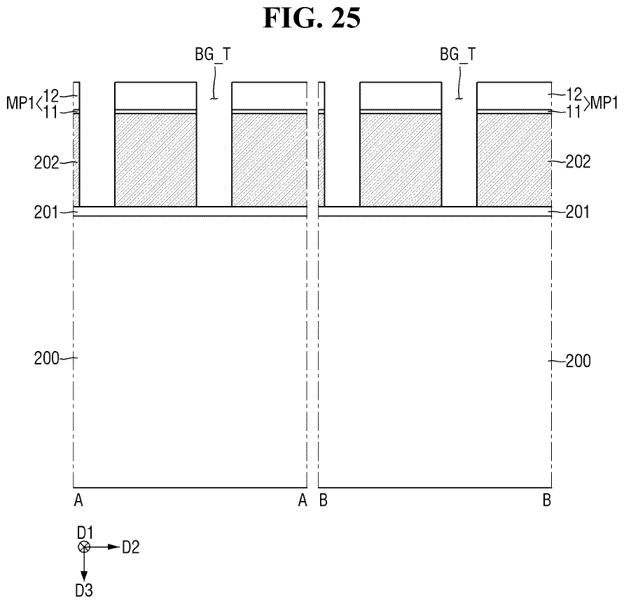

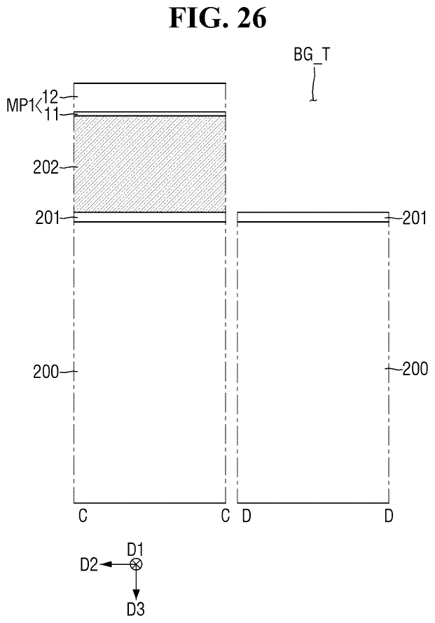

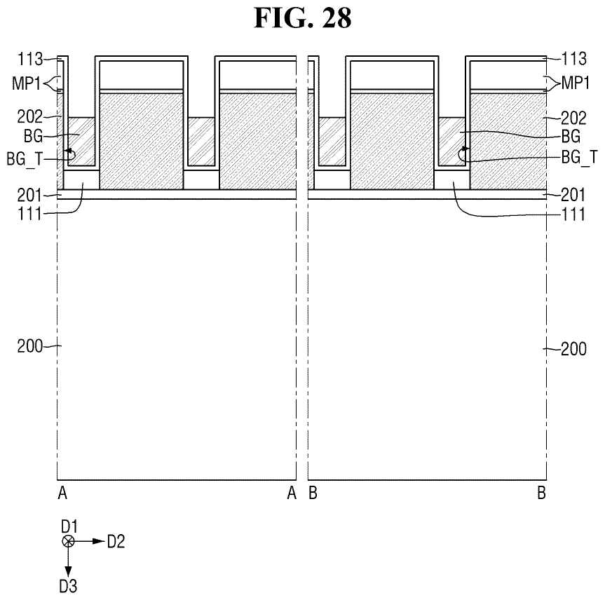

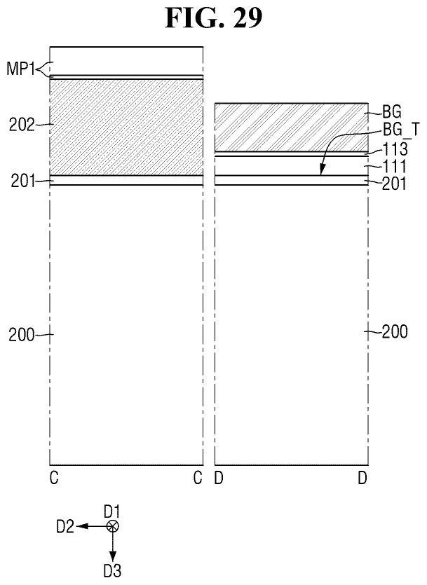

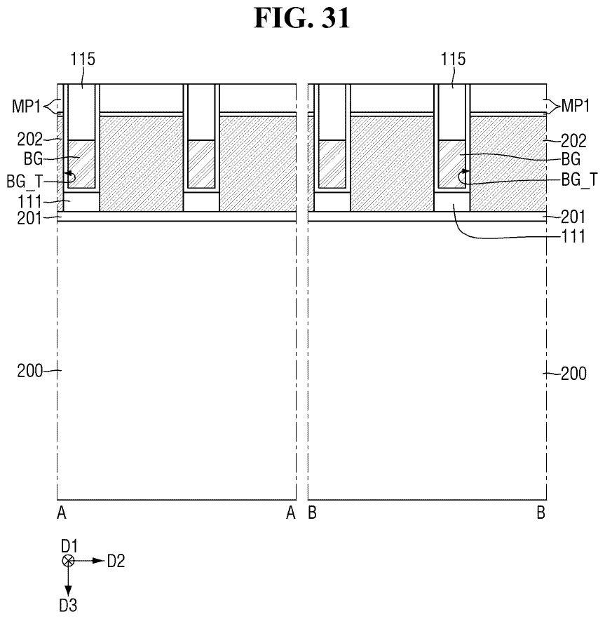

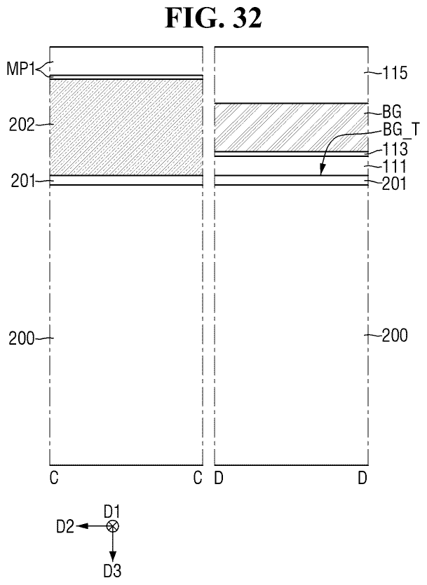

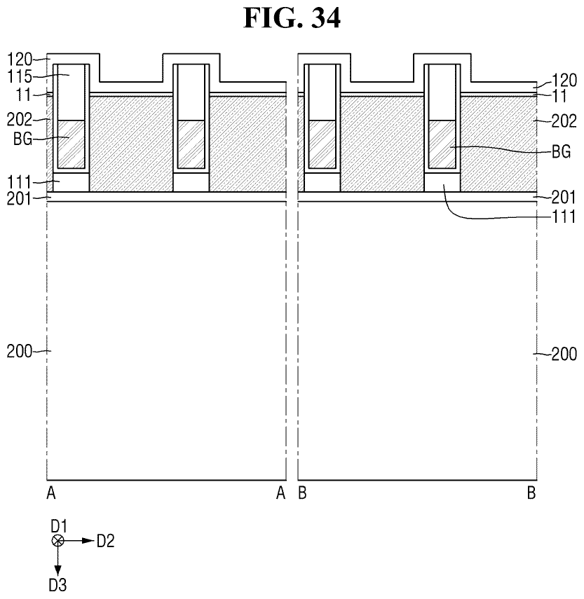

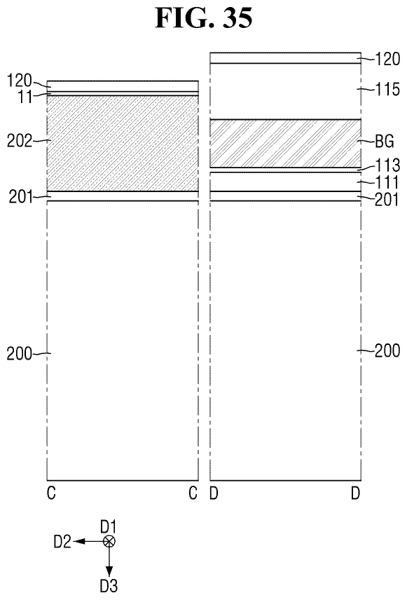

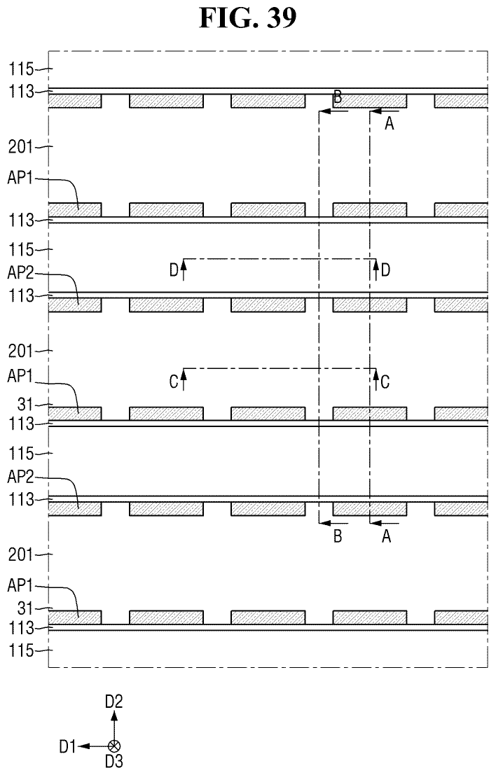

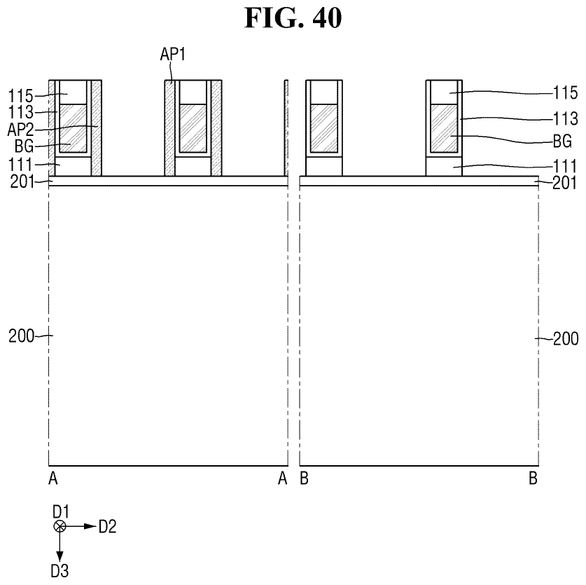

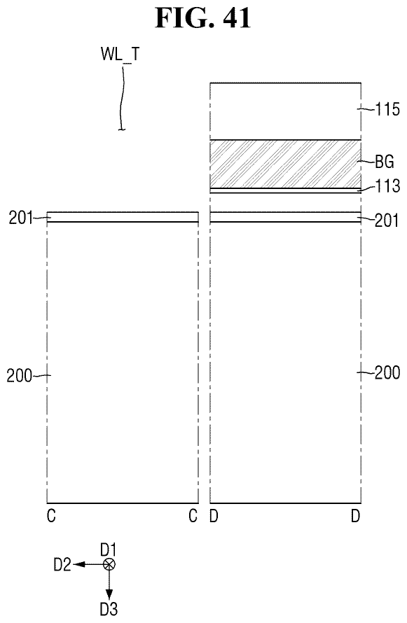

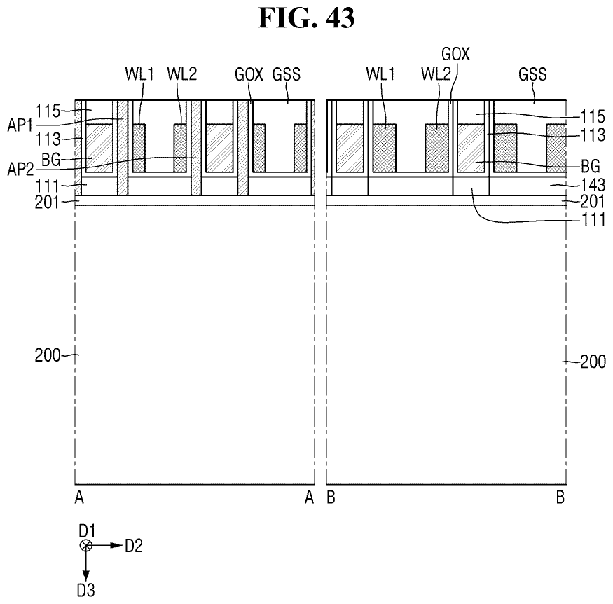

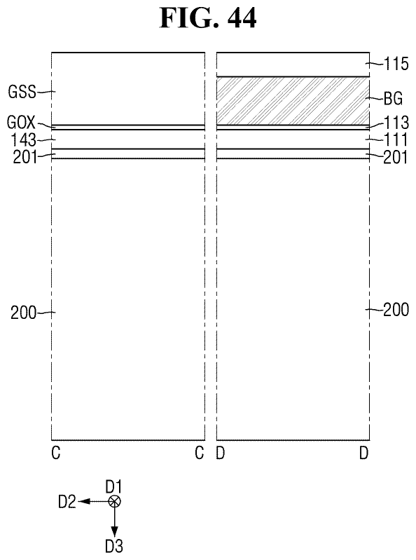

FIGS. 21 to 57 are diagrams for explaining a method for fabricating a semiconductor memory device according to some embodiments. Accordingly, the semiconductor memory device described using FIGS. 1 to 9 may be fabricated.

For reference, cutting lines and coordinate systems shown in FIGS. 21 to 46 are in a state in which cutting lines and coordinate systems of FIG. 1 are reversed in the first direction D1.

Referring to FIGS. 21 to 23, a sub-substrate structure including a sub-substrate 200, a buried insulating layer 201 and an active layer 202 may be provided.

The buried insulating layer 201 and the active layer 202 may be provided on the sub-substrate 200. The sub-substrate 200, the buried insulating layer 201 and the active layer 202 may be a silicon-on-insulator substrate (i.e., an SOI substrate). The sub-substrate 200 may be a semiconductor substrate. The sub-substrate 200 may be, for example, a silicon substrate, a germanium substrate, and/or a silicon-germanium substrate. In the following description, the sub-substrate 200 will be described as a silicon substrate.

The buried insulating layer 201 may be a buried oxide (BOX) formed by a SIMOX (separation by implanted oxygen) method or a bonding and layer transfer method. In contrast, the buried insulating layer 201 may be an insulating film formed by a chemical vapor deposition. The buried insulating layer 201 may include, for example, a silicon oxide film, a silicon nitride film, a silicon oxynitride film, and/or a low dielectric constant insulating film.

The active layer 202 may be a single crystal semiconductor film. The active layer 202 may be, for example, a single crystal silicon substrate, a germanium substrate, and/or a silicon-germanium substrate. The active layer 202 may have a first surface and a second surface that are opposite to each other in the third direction D3, and the second surface of the active layer 202 may be in contact with the buried insulating layer 201.

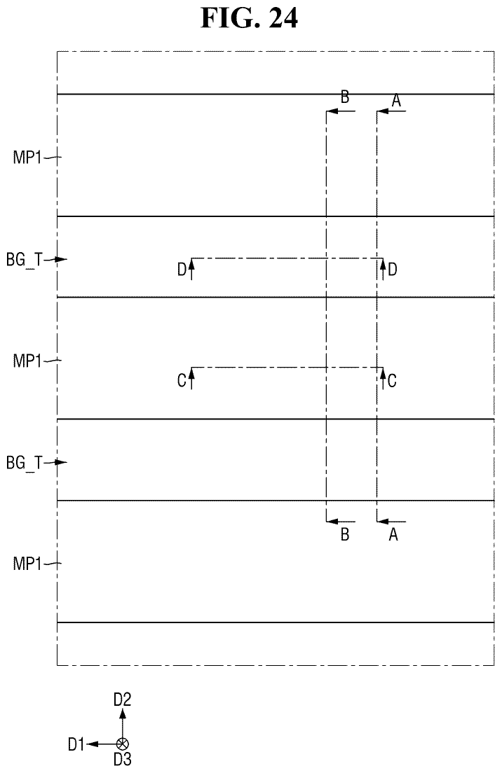

Referring to FIGS. 24 to 26, a mask pattern MP1 may be formed on the active layer 202.

The mask pattern MP1 may have linear openings extending along the first direction D1. The mask pattern MP1 may include a first lower mask film 11 and a first upper mask film 12 that are stacked in sequence. The first upper mask film 12 may be made of a material that has etching selectivity with respect to the first lower mask film 11. As an example, the first lower mask film 11 may include silicon oxide, and the first upper mask film 12 may include silicon nitride, but the embodiment is not limited thereto.

Subsequently, the active layer 202 may be anisotropically etched, by using the mask pattern MP1 as an etching mask. Accordingly, the back gate trenches BG_T extending in the first direction D1 may be formed on the active layer 202. The back gate trenches BG_T may expose the buried insulating layer 201, and may be spaced apart at regular intervals in the second direction D2.

Unlike the shown example, at least a part of the buried insulating layer 201 may be removed, while the back gate trench BG_T is being formed.

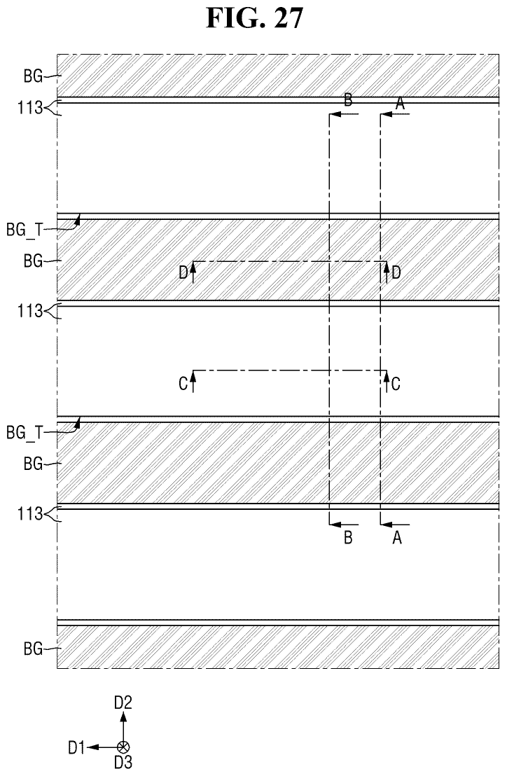

Referring to FIGS. 27 to 29, a back gate capping pattern 111 may be formed in the back gate trench BG_T.

The back gate capping pattern 111 may partially fill the back gate trench BG_T. The back gate capping pattern 111 may extend long in the first direction D1.

Thereafter, back gate insulating patterns 113 and back gate electrodes BG may be formed in the back gate trench BG_T. The back gate insulating pattern 113 and the back gate electrodes BG may be formed on the back gate capping pattern 111.

More specifically, the back gate insulating pattern 113 may be formed along the side wall of the back gate trench BG_T and the upper surface of the mask pattern MP. The back gate insulating pattern 113 may be formed along the exposed face of the back gate capping pattern 111. The back gate conductive film may be formed on the back gate insulating pattern 113. The back gate conductive film may fill the back gate trench BG_T.

Subsequently, the back gate conductive film may be etched to form back gate electrodes BG extending in the first direction D1. The back gate electrodes BG may partially fill the back gate trench BG_T.

Meanwhile, according to some embodiments, a gas phase doping (GPD) process or a plasma doping (PLAD) process may be performed, before forming the back gate insulating pattern 113. Through the aforementioned processes, the active layer 202 exposed by the back gate trench BG_T may be doped with impurities.

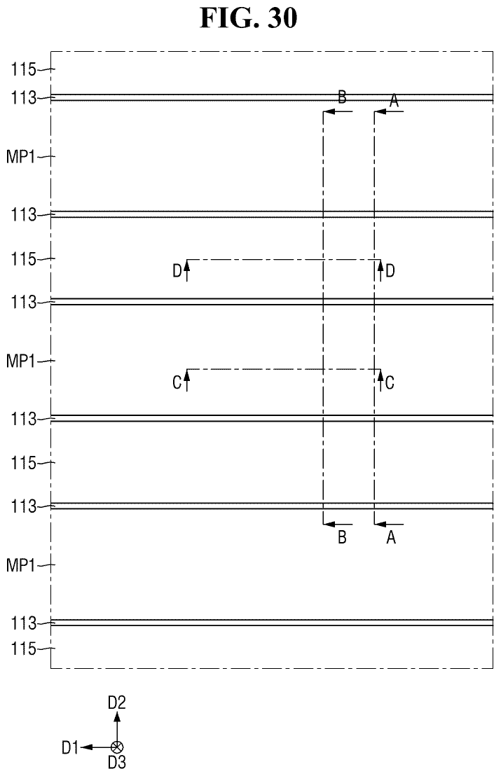

Referring to FIGS. 30 to 32, the back gate separation patterns 115 may be formed on the back gate electrode BG.

The back gate separation pattern 115 may fill the remainder of the back gate trench BG_T. When the back gate separation pattern 115 and the back gate insulating pattern 113 are formed of the same material (for example, silicon oxide), the back gate insulating pattern 113 on the upper surface of the mask pattern MP may be removed, while the back gate separation pattern 115 is being formed.

Meanwhile, before forming the back gate separation pattern 115, a gas phase doping (GPD) process or a plasma doping (PLAD) process may be performed. Accordingly, the active layer 202 may be doped with impurities through the back gate trench BG_T in which the back gate electrode BG is formed.

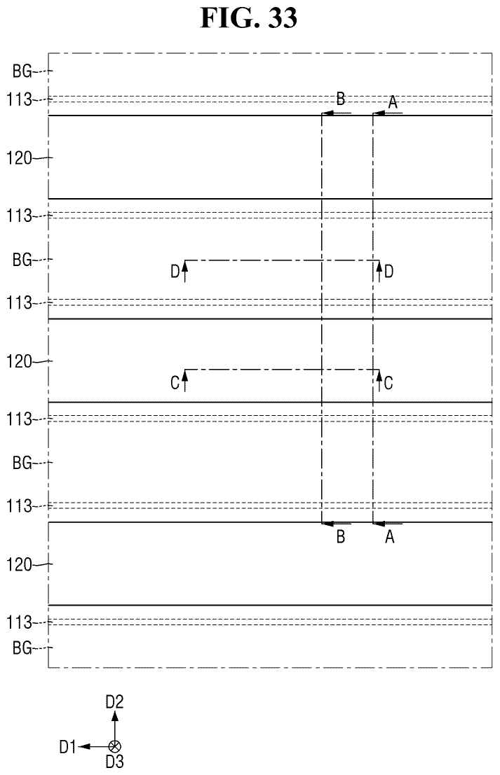

Referring to FIGS. 33 to 35, after forming the back gate separation pattern 115, the first upper mask film 12 may be removed.

The back gate separation patterns 115 may have shapes that protrude above the upper surface of the first lower mask film 11.

The spacer film 120 may then be formed along the upper surface of the first lower mask film 11, the side walls of the back gate insulating patterns 113, and the upper surfaces of the back gate separation patterns 115. The spacer film 120 may be formed to have a uniform thickness. The widths of the active patterns of the vertical channel transistors may be determined depending on the deposited thickness of the spacer film 120.

The spacer film 120 may be formed of an insulating material. The spacer film 120 may include, for example, silicon oxide, silicon oxynitride, silicon nitride, silicon carbide (SIC), silicon carbon nitride (SiCN), and/or combinations thereof.

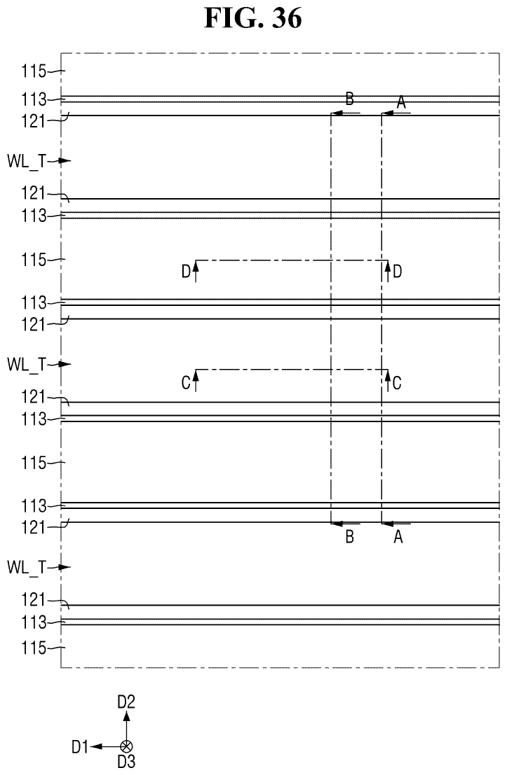

Referring to FIGS. 36 to 38, a pair of spacer patterns 121 may be formed on the side walls of the back gate insulating pattern 113, by performing an anisotropic etching process on the spacer film 120.

The anisotropic etching process may be performed on the active layer 202, by using the spacer pattern 121 as an etching mask. Accordingly, a pair of pre-active patterns PAP separated from each other may be formed on both sides of each back gate insulating pattern 113. As the pre-active patterns PAP are formed, the buried insulating layer 201 may be exposed.

The pre-active patterns PAP may have a line shape extending in the first direction D1 along with the back gate electrode BG. While the pre-active patterns PAP are being formed, a word line trench WL_T may be formed between the pre-active patterns PAP adjacent to each other in the second direction D2.

Referring to FIGS. 36 to 41, sacrificial films which fill the word line trench WL_T may be formed. The mask pattern may be formed on the sacrificial film. The mask pattern may have a line shape extending in the second direction D2. As another example, the mask pattern may have the form of a line extending in the diagonal direction with respect to the first direction D1 and the second direction D2. The sacrificial film may be etched using the mask pattern as an etch mask to form sacrificial openings inside the sacrificial film.

By etching the pre-active patterns PAP exposed to the sacrificial openings, the first active pattern AP1 and the second active pattern AP2 may be formed on both sides of the back gate electrode BG. The first active patterns AP1 may be formed on the first side wall of the back gate electrode BG to be spaced apart from each other in the first direction D1. The second active patterns AP2 may be formed on the second side wall of the back gate electrode BG to be spaced apart from each other in the first direction D1. Because the first active pattern AP1 and the second active pattern AP2 are formed, the sacrificial openings may expose a part of the back gate insulating pattern 113.

Next, the sacrificial film, the mask pattern, the spacer pattern 121, and the first lower mask film 11 may be removed. Accordingly, the first active pattern AP1 and the second active pattern AP2 may be exposed. Further, the buried insulating layer 201 may be exposed.

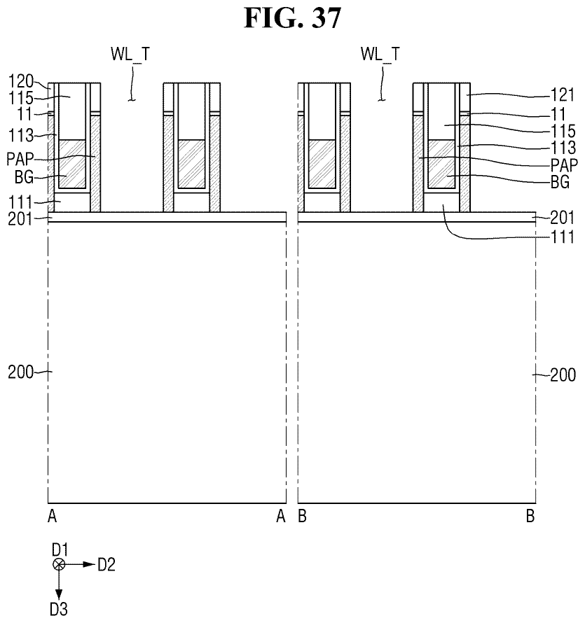

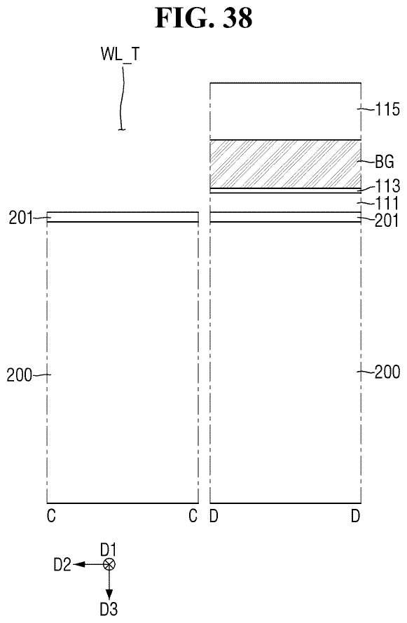

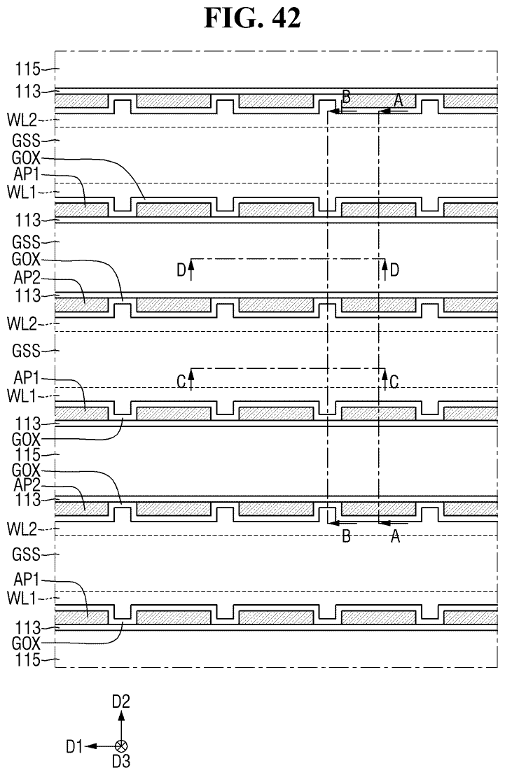

Referring to FIGS. 42 to 44, the gate capping pattern 143 may be formed inside the word line trench (WL_T of FIGS. 37 and 38).

The gate capping pattern 143 may partially fill the word line trench WL_T. The gate capping pattern 143 may be formed on the buried insulating layer 201.

Next, the gate insulating pattern GOX may be formed along the side walls of the first active pattern AP1, the side walls of the second active pattern AP2, and the upper surface of the back gate separation pattern 115. The gate insulating pattern GOX may be formed along the exposed face of the gate capping pattern 143.

The gate insulating pattern GOX may be formed, but not limited to, by using at least one of physical vapor deposition (PVD), thermal chemical vapor deposition (thermal CVD), low pressure chemical vapor deposition (LP-CVD), plasma enhanced chemical vapor deposition (PE-CVD) or atomic layer deposition (ALD) techniques.

Subsequently, a first word line WL1 and a second word line WL2 may be formed on the gate insulating pattern GOX. The first and second word lines WL1 and WL2 may be formed on the side walls of the first and second active patterns AP1 and AP2.

Formation of the first word line WL1 and the second word line WL2 may include deposing a gate conductive film on the gate insulating pattern GOX, and then performing an anisotropic etching process on the gate conductive film. Here, the deposited thickness of the gate conductive film may be smaller than half the width of the word line trench (WL_T of FIGS. 36 and 37).

At the time of the anisotropic etching process on the gate conductive film, the gate insulating pattern GOX may be used as an etching stop film. Unlike the shown example, the exposed gate insulating pattern GOX between the first word line WL1 and the second word line WL2 may be removed by etching.

The upper surface of the first word line WL1 and the upper surface of the second word line WL2 may be located at a lower level than the upper surfaces of the first and second active patterns AP1 and AP2, i.e., closer to the sub-substrate 200.

As an example, after forming the first and second word lines WL1 and WL2, a gas phase doping (GPD) process or a plasma doping (PLAD) process may be performed. Accordingly, impurities may be doped into the first and second active patterns AP1 and AP2 through the gate insulating pattern GOX exposed by the first and second word lines WL1 and WL2.

Subsequently, the gate separation pattern GSS may be formed on the first word line WL1 and the second word line WL2.

For example, the upper surface of the gate separation pattern GSS may be disposed on the same plane as the upper surface of the back gate separation pattern 115.

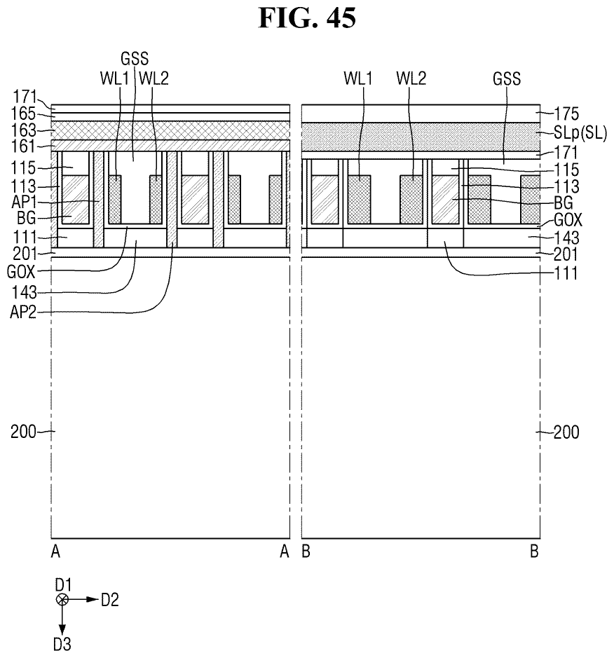

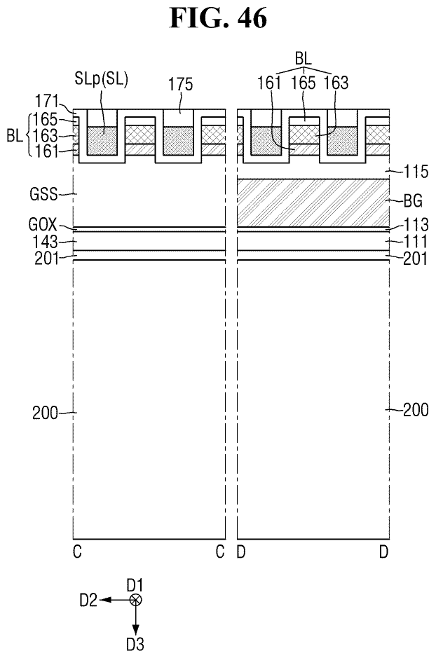

Referring to FIGS. 45 and 46, bit lines BL extending in the second direction D2 may be formed on the gate separation pattern GSS and the back gate separation pattern 115.

The bit line BL may include a bit line mask pattern 165, a metal pattern 163, and a semiconductor pattern 161. During the formation of the bit line BL, a part of the back gate separation pattern 115 and a part of the gate separation pattern GSS may be etched.

Subsequently, the shielding conductive pattern SL may be formed between bit lines BL adjacent in the first direction D1.

More specifically, the shielding insulating liner 171 may be formed along the profile of the bit line BL. The shielding insulating liner 171 may define a shielding region between the bit lines BL adjacent in the first direction D1. The shielding conductive film may be formed on the shielding insulating liner 171. The shielding conductive film may fill the shielding region defined by the shielding insulating liner 171. At least a part of the shielding conductive film may be recessed to form the shielding conductive pattern SL. As an example, when the shielding conductive film formed on the bit line BL is completely removed, the shielding conductive pattern SL may include a plurality of linear shielding conductive line patterns SLp. As another example, when a part or all of the shielding conductive film formed on the bit line BL is not removed, the shielding conductive pattern SL may include a flat shielding conductive plate (SLh of FIGS. 15 and 16) and a plurality of linear shielding conductive line patterns SLp. A shielding insulating capping film 175 may be formed on the shielding conductive pattern SL.

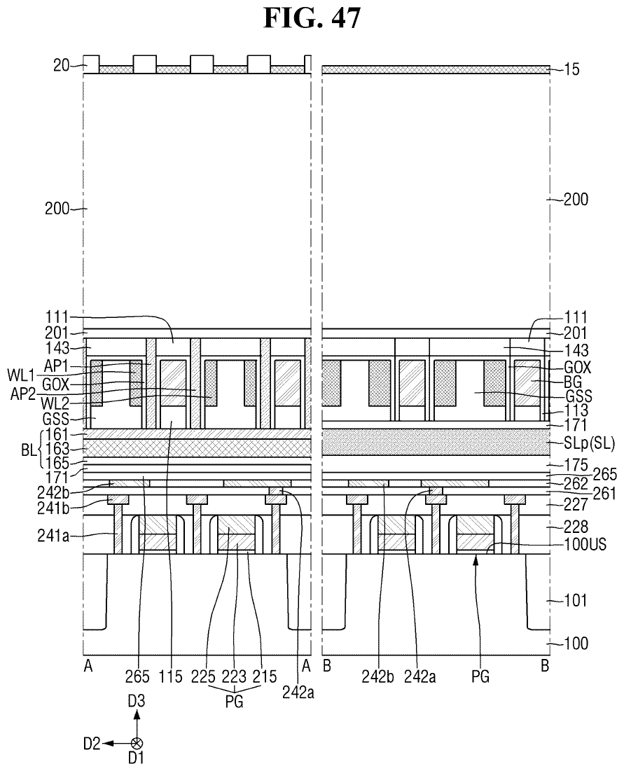

Referring to FIG. 47, a peri-gate structure PG may be formed on the substrate 100.

A sub-substrate 200 on which back gate electrodes BG, word lines WL1 and WL2, active patterns AP1 and AP2, bit lines BL and shielding conductive patterns SL are formed may be bonded with the substrate 100. The substrate 100 and the sub-substrate 200 may be bonded such that the bit line BL and the peri-gate structure PG face each other.

After bonding the substrate 100 and the sub-substrate 200, a back lapping process of removing a part of the sub-substrate 200 may be performed.

The electrode mask pattern 20 and the metal mask pattern 15 may then be formed on the sub-substrate 200. The electrode mask pattern 20 may be formed at a position corresponding to the storage electrode 251 of FIG. 2. The metal mask pattern 15 may partially or completely fill the space between the electrode mask patterns 20.

The electrode mask pattern 20 may include, for example, an insulating material. The electrode mask pattern 20 may include at least one of an inorganic material and an organic material. The metal mask pattern 15 may include a metal. For example, the metal mask pattern 15 may include a metal that may be used as a catalyst in metal assisted chemical etching (MACE). The metal mask pattern 15 may include, but not limited to, at least one of gold (Au), platinum (Pt), palladium (Pd), silver (Ag), nickel (Ni), aluminum (Al), copper (Cu), and/or iron (Fc).

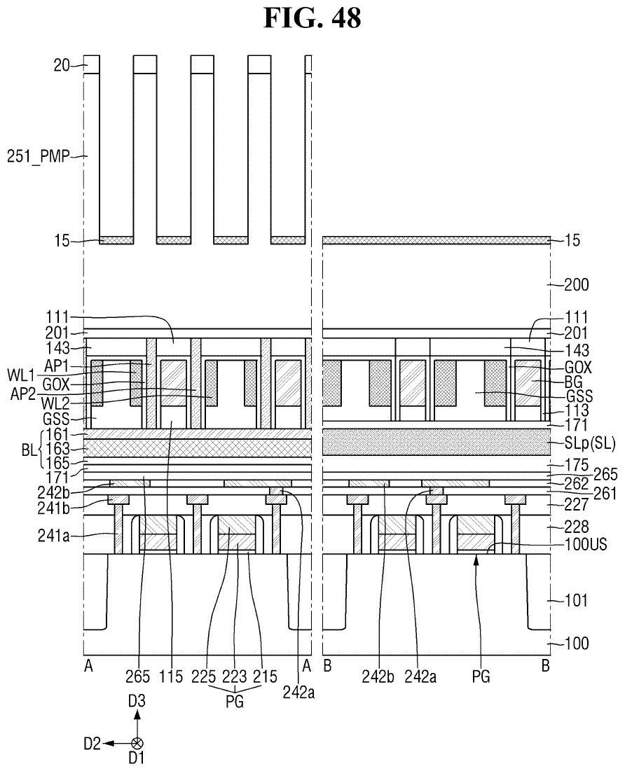

Referring to FIG. 48, a part of the sub-substrate 200 may be etched using the metal assisted chemical etching (MACE) to form a pre-semiconductor mold pattern 251_PMP.

The pre-semiconductor mold pattern 251_PMP may be formed by removing the sub-substrate 200 that overlaps the metal mask pattern 15 in the third direction D3.

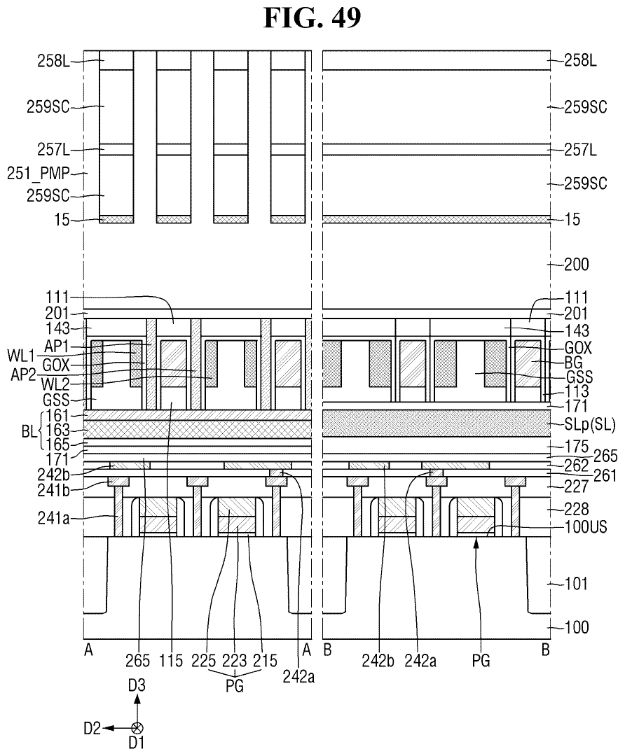

Referring to FIG. 49, a lower sacrificial mold insulating film 259SC, a first lower electrode support film 257L, an upper sacrificial mold insulating film 259SC, and a second lower electrode support film 258L may be formed sequentially on the metal mask pattern 15.

The electrode mask pattern 20 may be removed, while the lower sacrificial mold insulating film 259SC, the first lower electrode support film 257L, the upper sacrificial mold insulating film 259SC, and the second lower electrode support film 258L are being formed.

More specifically, a lower sacrificial mold insulating film 259SC may be formed. For example, a lower sacrificial insulating film may be formed on the metal mask pattern 15. The lower sacrificial insulating film may cover, overlap, or be on the entire side wall of the pre-semiconductor mold pattern 251_PMP. The lower sacrificial mold insulating film 259SC may be formed by recessing a part of the lower sacrificial insulating film.

Subsequently, a first lower electrode support film 257L may be formed on the lower sacrificial mold insulating film 259SC. For example, a pre-lower electrode support film may be formed on the lower sacrificial mold insulating film 259SC. The first lower electrode support film 257L may be formed on the lower sacrificial mold insulating film 259SC, by recessing a part of the pre-lower electrode support film.

Subsequently, an upper sacrificial mold insulating film 259SC may be formed on the first lower electrode support film 257L. The formation of the upper sacrificial mold insulating film 259SC may be substantially the same as the process of forming the lower sacrificial mold insulating film 259SC.

Subsequently, a second lower electrode support film 258L may be formed on the upper sacrificial mold insulating film 259SC.

The upper sacrificial mold insulating film 259SC and the lower sacrificial mold insulating film 259SC may include an insulating material. The upper sacrificial mold insulating film 259SC and the lower sacrificial mold insulating film 259SC may include a material having an etching selectivity with respect to silicon.

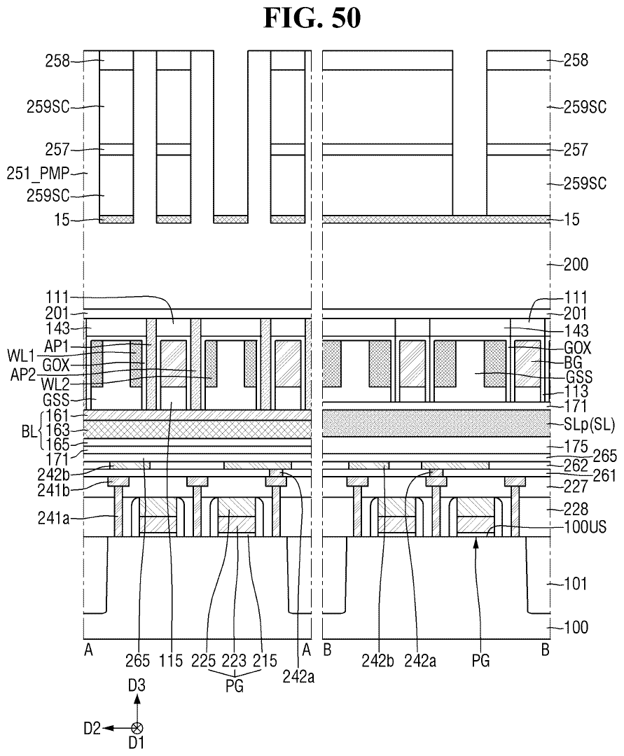

Referring to FIGS. 49 and 50, a first lower electrode support 257 and a second lower electrode support 258 may be formed by patterning the first lower electrode support film 257L and the second lower electrode support film 258L.

While the first lower electrode support 257 and the second lower electrode support 258 are being formed, a part of the upper sacrificial mold insulating film 259SC and a part of the lower sacrificial mold insulating film 259SC may also be removed.

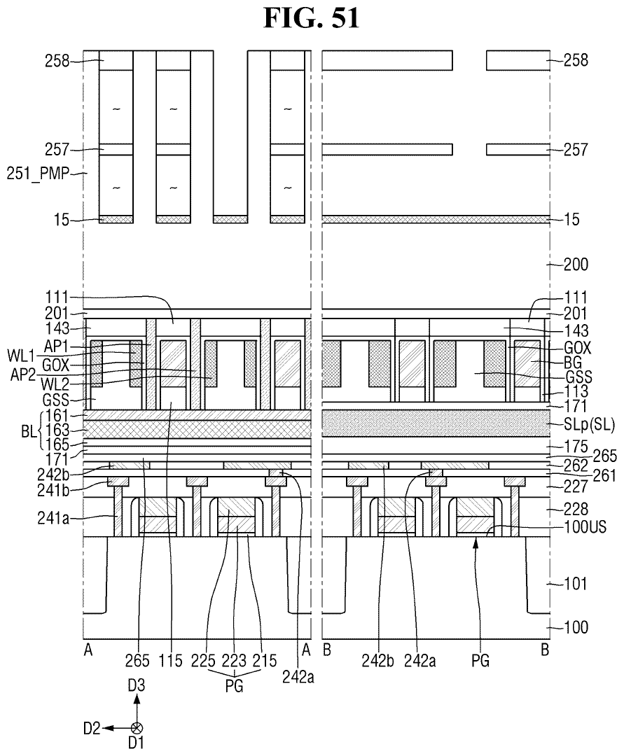

Referring to FIGS. 50 and 51, the upper sacrificial mold insulating film 259SC and the lower sacrificial mold insulating film 259SC are removed.

The upper sacrificial mold insulating film 259SC and the lower sacrificial mold insulating film 259SC are removed, and a mold space may be formed between the first lower electrode support 257 and the second lower electrode support 258. The mold space may be an empty space that is not filled with a material.

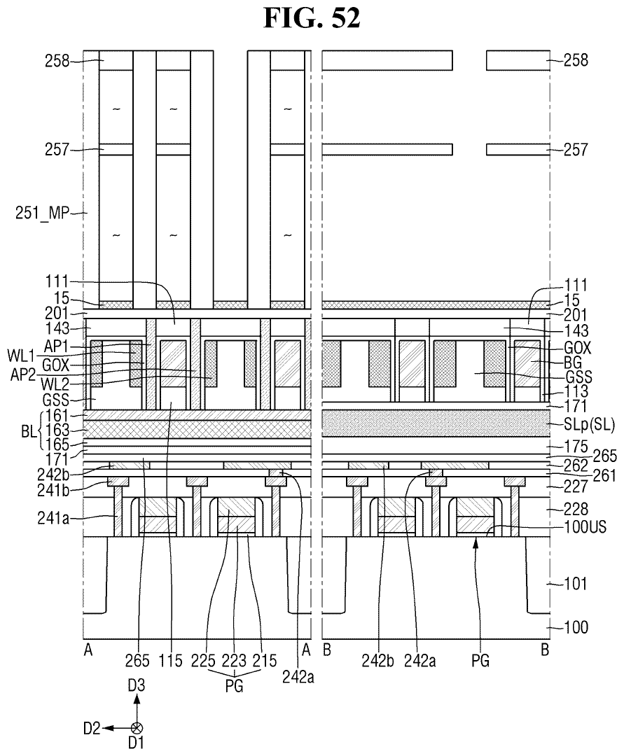

Referring to FIGS. 51 and 52, the remainder of the sub-substrate 200 may be etched by using metal assisted chemical etching (MACE) to form a semiconductor mold pattern 251_MP.

The remainder of the sub-substrate 200 that overlaps the metal mask pattern 15 in the third direction D3 may be removed to form the semiconductor mold pattern 251_MP. A plurality of semiconductor mold patterns 251_MP may be formed on the buried insulating layer 201.

The semiconductor mold pattern 251_MP may be formed on the buried insulating layer 201, by removing the sub-substrate 200 that overlaps the metal mask pattern 15 in the third direction D3 by using metal assisted chemical etching (MACE).

When an aspect ratio of the semiconductor mold pattern 251_MP increases, the semiconductor mold pattern 251_MP may bend. In order to prevent the semiconductor mold pattern 251_MP from bending, the first lower electrode support 257 and the second lower electrode support 258 explained using FIGS. 48 to 51 may be formed.

When the semiconductor mold pattern 251_MP has an aspect ratio to such an extent that it does not bend, the process of forming the first lower electrode support 257 and the second lower electrode support 258 may be omitted.

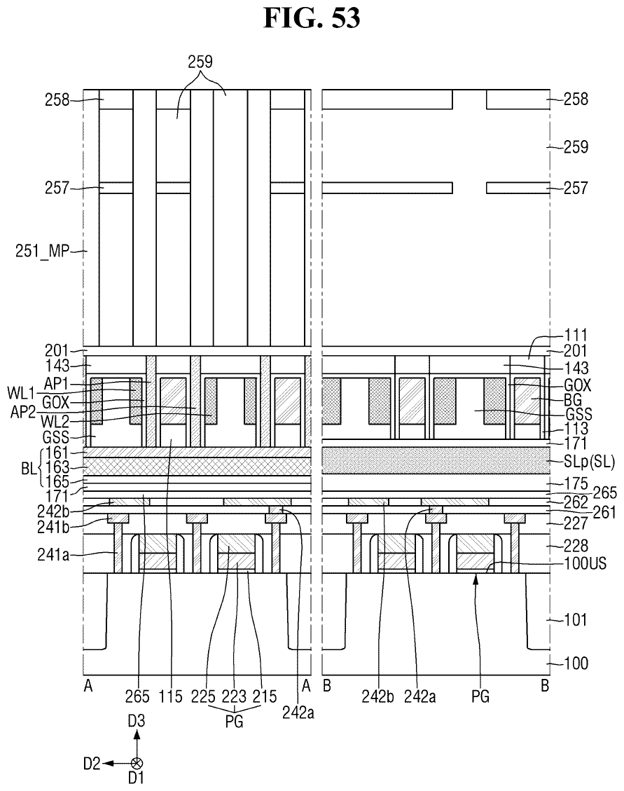

Referring to FIGS. 52 and 53, the metal mask pattern 15 used in the metal assisted chemical etching (MACE) process may be removed.

The metal mask pattern 15 may be removed to expose the buried insulating layer 201.

A sacrificial mold film 259 may then be formed on the buried insulating layer 201. The sacrificial mold film 259 may wrap the semiconductor mold pattern 251_MP. The sacrificial mold film 259 may cover, overlap, or be on the side walls of the semiconductor mold pattern 251_MP. The sacrificial mold film 259 may fill a mold space formed by removing the sub-substrate (200 of FIGS. 47 to 52). The sacrificial mold film 259 may include an insulating material.

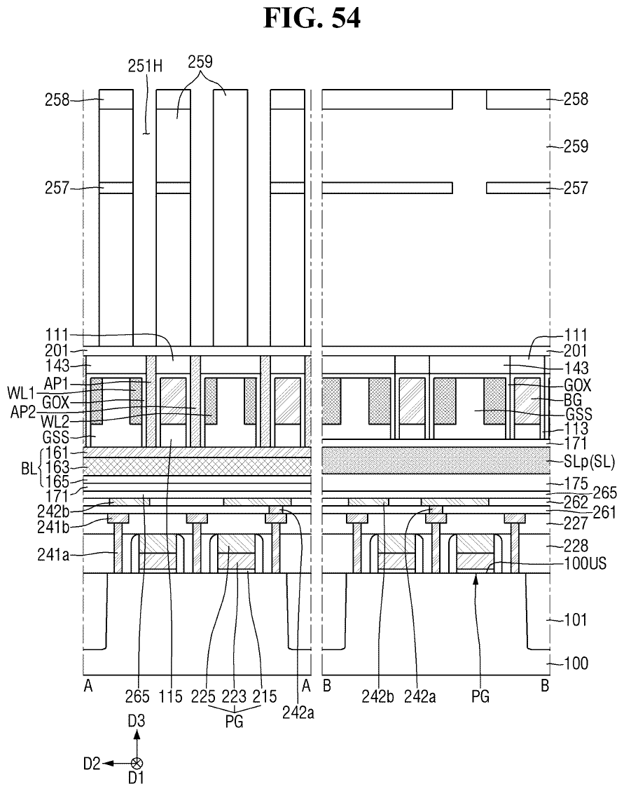

Referring to FIGS. 53 and 54, the semiconductor mold pattern 251_MP may be removed to form a lower electrode hole 251H inside the sacrificial mold film 259.

The semiconductor mold pattern 251_MP is removed, and the lower electrode hole 251H may expose the buried insulating layer 201.

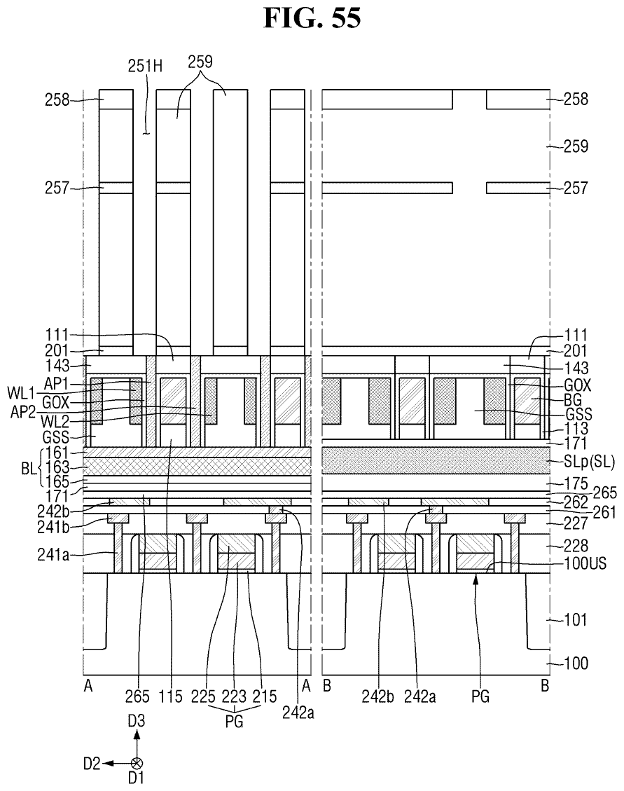

Referring to FIGS. 54 and 55, by removing a part of the buried insulating layer 201, the lower electrode hole 251H may extend to the first active pattern AP1 and the second active pattern AP2.

By removing at least a part of the buried insulating layer 201 that overlaps the lower electrode hole 251H in the third direction D3, a lower electrode hole 251H that exposes the first active pattern AP1 and the second active pattern AP2 may be formed. The lower electrode hole 251H may be formed inside the sacrificial mold film 259 and the buried insulating layer 201.

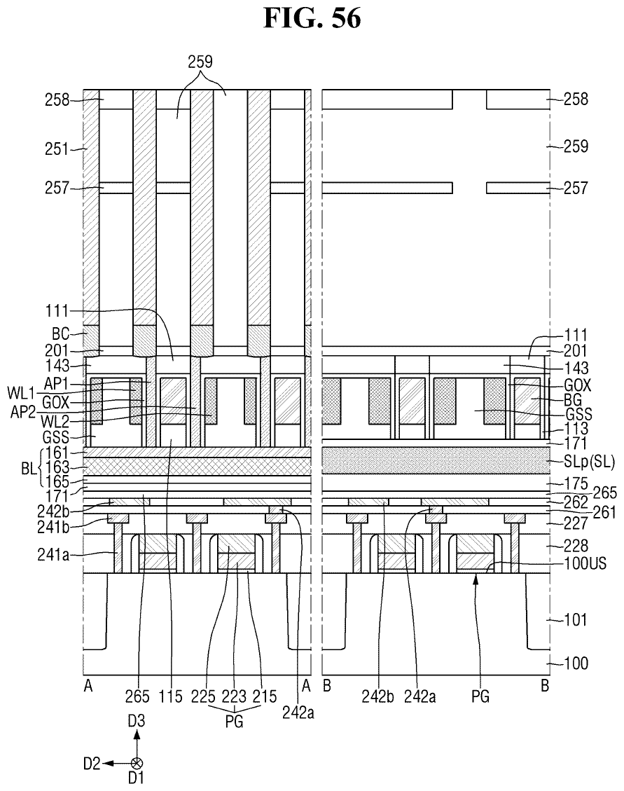

Referring to FIG. 56, the contact structure BC and the storage electrode 251 may be sequentially formed inside the lower electrode hole 251H.

The contact structure BC and the storage electrode 251 may be formed inside the sacrificial mold film 259 and the buried insulating layer 201.

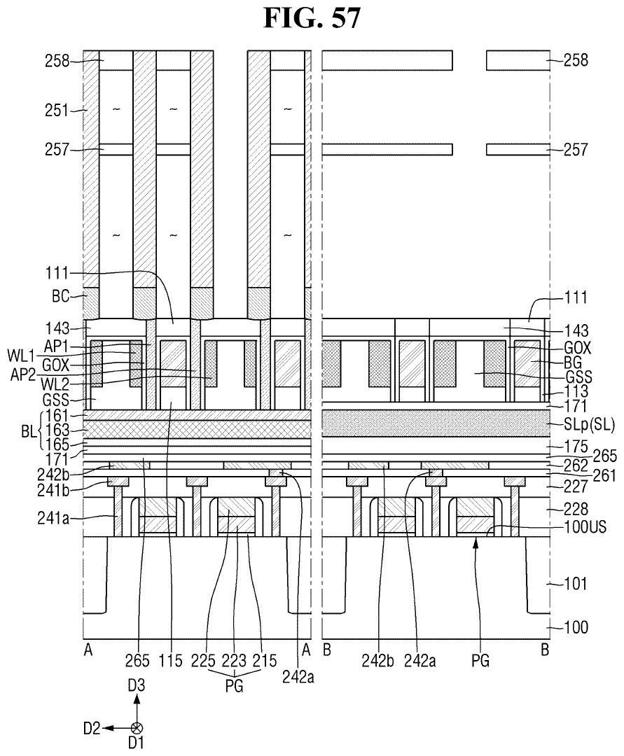

Referring to FIGS. 56 and 57, by removing the sacrificial mold film 259 and the buried insulating layer 201, the side walls of the contact structure BC and the side walls of the storage electrode 251 may be exposed.

The gate capping pattern 143 and the back gate capping pattern 111 may also be exposed.

Next, referring to FIGS. 2 and 3, a capacitor dielectric film 253 and a plate electrode 255 may be formed on the contact structure BC and the storage electrode 251.

In order to increase the capacitance of the capacitor, it is necessary to increase the height of the storage electrode 251. In the semiconductor memory device of the present invention, since the storage electrode 251 uses the sub-substrate 200 that is removed after wafer bonding, the thickness of the sub-substrate 200 that remains after the lapping process may be freely adjusted. When the thickness of the sub-substrate 200 increases, the height of the semiconductor mold pattern 251_MP used to form the storage electrode 251 also increases. Accordingly, when the height of the semiconductor mold pattern 251_MP increases, the height of the storage electrode 251 also increases, and therefore, the capacitance of the capacitor may increase. The performance and reliability of the semiconductor memory device may be improved, accordingly.

Although the embodiments of the present disclosure have been described with reference to the accompanying drawings, the present disclosure is not limited to the above embodiments and may be implemented in various different forms. Those of ordinary skill in the technical field to which the present disclosure belongs will be able to understand that the present disclosure may be implemented in other specific forms without changing the technical idea or characteristics of the present disclosure. Therefore, it should be understood that the embodiments as described above are not restrictive but illustrative in all respects.

1. A semiconductor memory device comprising:
a peri-gate structure on a substrate;
a bit line on the peri-gate structure, wherein the bit line extends in a first direction;
an active pattern on the bit line, wherein the active pattern includes a first surface and a second surface opposite to each other in a second direction, and a first side wall and a second side wall opposite to each other in the first direction, and wherein the first surface of the active pattern is in contact with the bit line;
a word line on the first side wall of the active pattern, wherein the word line extends in a third direction that intersects the first direction and the second direction;
a contact structure on the active pattern, wherein the contact structure includes an upper surface and a bottom surface opposite to each other in the second direction, wherein the bottom surface of the contact structure is in contact with the second surface of the active pattern; and
a data storage pattern on the upper surface of the contact structure, and includes a lower electrode and a capacitor dielectric film,
wherein the contact structure includes a side wall between the upper surface of the contact structure and the bottom surface of the contact structure, and
wherein the capacitor dielectric film extends along the side wall of the contact structure, and is in contact with the side wall of the contact structure.

2. The semiconductor memory device of claim 1,
wherein the lower electrode includes a bottom surface that faces the contact structure, and
wherein a width of the bottom surface of the lower electrode in the first direction is substantially equal to a width of the upper surface of the contact structure in the first direction.

3. The semiconductor memory device of claim 1,
wherein the contact structure includes a contact plug pattern comprising a conductive material, and
wherein the contact plug pattern is in contact with the capacitor dielectric film.

4. The semiconductor memory device of claim 1,
wherein the contact structure includes a contact plug pattern comprising a conductive material, and a contact insulating spacer that extends along a side wall of the contact plug pattern, and
wherein the contact insulating spacer is in contact with the capacitor dielectric film.

5. The semiconductor memory device of claim 1,
wherein the data storage pattern includes an upper electrode on the capacitor dielectric film, and
wherein the upper electrode is on the side wall of the contact structure.

6. The semiconductor memory device of claim 1, further comprising:
a lower electrode support in contact with the side wall of the lower electrode.

7. The semiconductor memory device of claim 6,
wherein the lower electrode support includes an upper surface and a bottom surface that are opposite to each other in the second direction,
wherein the bottom surface of the lower electrode support faces the active pattern, and
wherein at least one of the upper surface of the lower electrode support and the bottom surface of the lower electrode support includes a curved surface.

8. The semiconductor memory device of claim 1, further comprising:
a shielding conductive pattern on the peri-gate structure, and includes a shielding conductive line pattern that extends in the first direction along the side wall of the bit line.

9. The semiconductor memory device of claim 8,
wherein the shielding conductive pattern further includes a shielding conductive plate,
wherein the shielding conductive line pattern protrudes from the shielding conductive plate in the second direction, and
wherein the bit line is on the shielding conductive plate.

10. The semiconductor memory device of claim 1, further comprising:
a back gate electrode on the second side wall of the active pattern on the bit line, wherein the back gate electrode extends in the third direction.

11. A semiconductor memory device comprising:
a peri-gate structure on a substrate;
a bit line on the peri-gate structure, wherein the bit line extends in a first direction;
an active pattern on the bit line, wherein the active pattern includes a first surface and a second surface opposite to each other in a second direction, and a first side wall and a second side wall opposite to each other in the first direction, and wherein the first surface of the active pattern is in contact with the bit line;
a word line on the first side wall of the active pattern, wherein the word line extends in a third direction that intersects the first direction and the second direction;
a contact structure on the active pattern, wherein the contact structure includes an upper surface and a bottom surface opposite to each other in the second direction, wherein the bottom surface of the contact structure is in contact with the second surface of the active pattern; and
a data storage pattern on the upper surface of the contact structure,
wherein the data storage pattern includes a lower electrode in contact with the upper surface of the contact structure, a capacitor dielectric film on the lower electrode, and an upper electrode on the capacitor dielectric film,
wherein the upper electrode includes a bottom surface that faces the bit line, and
wherein a distance from the upper surface of the bit line to the upper surface of the contact structure is greater than a distance from the upper surface of the bit line to the bottom surface of the upper electrode.

12. The semiconductor memory device of claim 11,
wherein the upper electrode is on a side wall of the contact structure.

13. The semiconductor memory device of claim 11,
wherein the capacitor dielectric film extends along a side wall of the contact structure, and contacts the side wall of the contact structure.

14. The semiconductor memory device of claim 11,
wherein the lower electrode includes a bottom surface that faces the contact structure, and
wherein a width of the bottom surface of the lower electrode in the first direction is substantially equal to a width of the upper surface of the contact structure in the first direction.

15. The semiconductor memory device of claim 11,
wherein the contact structure includes a contact plug pattern comprising a conductive material, and
wherein the contact plug pattern includes a side wall of the contact structure.

16. The semiconductor memory device of claim 11,
wherein the contact structure includes a contact plug pattern comprising a conductive material, and a contact insulating spacer that extends along a side wall of the contact plug pattern, and
wherein the contact insulating spacer includes the side wall of the contact structure.

17. The semiconductor memory device of claim 11, further comprising:
a back gate electrode on the second side wall of the active pattern on the bit line, wherein the back gate electrode extends in the third direction; and
a shielding conductive pattern on the peri-gate structure, and includes a shielding conductive line pattern that extends in the first direction along the side wall of the bit line.

18. A semiconductor memory device comprising:
a peri-gate structure on a substrate;
a bit line on the peri-gate structure, wherein the bit line extends in a first direction;
a shielding conductive pattern on the peri-gate structure, wherein the shielding conductive pattern includes a shielding conductive line pattern that extends in the first direction along a side wall of the bit line;
a word line on the bit line and the shielding conductive pattern, wherein the word line extends in a second direction, and includes an upper surface and a bottom surface opposite to each other in a third direction, and wherein the bottom surface of the word line faces the bit line;
a back gate electrode on the bit line and the shielding conductive pattern, wherein the back gate electrode extends in the second direction, and includes an upper surface and a bottom surface opposite to each other in the third direction, wherein the bottom surface of the back gate electrode faces the bit line;
a word line capping pattern on the upper surface of the word line;
a back gate capping pattern on the upper surface of the back gate electrode;
an active pattern between the word line and the back gate electrode, wherein the active pattern includes a first surface and a second surface opposite to each other in the third direction, and wherein the first surface of the active pattern contacts the bit line;
a contact structure on the active pattern, wherein the contact structure is in contact with the second surface of the active pattern; and
a data storage pattern on the contact structure, wherein the data storage pattern includes a lower electrode and a capacitor dielectric film,
wherein the capacitor dielectric film is in contact with the word line capping pattern and the back gate capping pattern.

19. The semiconductor memory device of claim 18,
wherein the contact structure includes an upper surface and a bottom surface opposite to each other in the third direction,
wherein the bottom surface of the contact structure is in contact with the active pattern, and
wherein the upper surface of the contact structure protrudes in the third direction beyond the word line capping pattern and the back gate capping pattern.

20. The semiconductor memory device of claim 18,
wherein the capacitor dielectric film extends along the side wall of the contact structure, and is in contact with the side wall of the contact structure.

21.-22. (canceled)
